(19) United States
(12) Patent Application Publication
(10) Pub. No.: US 2018/0294225 A1
(43) Pub. Date: Oct. 11, 2018

(54) THREE-DIMENSIONAL SEMICONDUCTOR MEMORY DEVICE AND METHOD OF FABRICATING THE SAME

(71) Applicant: Samsung Electronics Co., Ltd., Suwon-si (KR)

(72) Inventors: TaeHee Lee, Suwon-si (KR); Juyeon LEE, Yongin-si (KR); Jeehoon HWANG, Hwaseong-si (KR)

(73) Assignee: Samsung Electronics Co., Ltd., Suwon-si (KR)

(21) Appl. No.: 15/855,416

(22) Filed: Dec. 27, 2017

(30) Foreign Application Priority Data
Apr. 7, 2017 (KR) 10-2017-0045114

(51) Int. Cl. H01L 23/528; H01L 27/11556; H01L 27/11582; H01L 27/11526; H01L 27/11573

(52) U.S. Cl. CPC H01L 23/5283; H01L 27/11556; H01L 27/11573; H01L 27/11526; H01L 27/11582

(57) ABSTRACT

Provided are a three-dimensional semiconductor memory device and a method of fabricating the same. The device may include a substrate a substrate including a peripheral circuit region and a cell array region, an electrode structure including a plurality of electrodes vertically stacked on the cell array region of the substrate, a peripheral logic circuit provided on the peripheral circuit region of the substrate, the peripheral logic circuit including a first impurity region doped with first impurities, a peripheral contact plug connected to the first impurity region, and a second impurity region between the first impurity region and the peripheral contact plug, the second impurity region being including second impurities different from the first impurities. The peripheral contact plug includes a lower portion contacting the second impurity region, and an upper portion continuously extending from the lower portion a lower width of each of the lower and upper portions is less than an upper width thereof, and the upper width of the lower portion is greater than the lower width of the upper portion.

### CROSS-REFERENCE TO RELATED APPLICATIONS

This U.S. non-provisional patent application claims priority under 35 U.S.C. § 119 to Korean Patent Application No. 10-2017-0045114, filed on Apr. 7, 2017, in the Korean Intellectual Property Office, the entire contents of which are hereby incorporated herein by reference.

### BACKGROUND

The disclosure relates to a highly-integrated three-dimensional semiconductor memory device and a method of fabricating the same.

Higher integration of semiconductor devices is desired to satisfy consumer demands for performance and price. In the case of semiconductor devices, since their integration is an important factor in determining product prices, increased integration is especially desired. In the case of conventional two-dimensional or planar semiconductor devices, since their integration is mainly determined by the area occupied by a unit memory cell, integration is greatly influenced by the level of a fine pattern forming technology. However, the expensive process equipment needed to increase pattern fineness sets a practical limit on integration complexity for two-dimensional or planar semiconductor devices. To overcome such a limitation, there have been recently proposed three-dimensional semiconductor memory devices including three-dimensionally arranged memory cells.

### SUMMARY

Some embodiments of inventive concepts provide a three-dimensional semiconductor memory device with improved integration density and a method of fabricating the same.

According to some embodiments of inventive concepts, a three-dimensional semiconductor memory device may include a substrate including a peripheral circuit region and a cell array region, an electrode structure including a plurality of electrodes vertically stacked on the cell array region of the substrate, a peripheral logic circuit provided on the peripheral circuit region of the substrate, the peripheral logic circuit including a first impurity region doped with first impurities, a peripheral contact plug connected to the first impurity region, and a second impurity region between the first impurity region and the peripheral contact plug, the second impurity region being including second impurities different from the first impurities. The peripheral contact plug includes a lower portion contacting the second impurity region, and an upper portion continuously extending from the lower portion a lower width of each of the lower and upper portions is less than an upper width thereof, and the upper width of the lower portion is greater than the lower width of the upper portion.

According to some embodiments of inventive concepts, a three-dimensional semiconductor memory device may include a substrate including a peripheral circuit region and a cell array region, an electrode structure including a plurality of electrodes vertically stacked on the cell array region of the substrate, a peripheral logic circuit provided on the peripheral circuit region of the substrate, the peripheral logic circuit comprising a peripheral gate stack and source/drain impurity regions, the peripheral gate stack including a first side and a second side, the source/drain regions being at both sides of the peripheral gate stack, and peripheral contact plugs connected to the source/drain impurity regions, respectively. Each of the source/drain impurity regions includes a first impurity region doped with first impurities, and a second impurity region including second impurities different from the first impurities. The peripheral contact plugs are in contact with the second impurity regions of the source/drain impurity regions.

According to some embodiments of inventive concepts, a method of fabricating a three-dimensional semiconductor memory device may include providing a substrate including a peripheral circuit region and a cell array region, forming a peripheral structure on the peripheral circuit region of the substrate, the peripheral structure including a peripheral gate stack, source/drain impurity regions at both sides of the peripheral gate stack, and a lower insulating layer covering the peripheral gate stack and the source/drain impurity regions, forming sacrificial plugs penetrating the lower insulating layer and in contact with the source/drain impurity regions, respectively, forming an electrode structure spaced apart from the peripheral structure, the electrode structure including electrodes vertically stacked on the cell array region of the substrate, forming an upper insulating layer covering the electrode structure, the peripheral structure, and the sacrificial plug, forming upper contact holes penetrating the upper insulating layer and expose the sacrificial plugs, respectively, removing the sacrificial plugs exposed by the upper contact holes, and forming peripheral contact plugs in the lower and upper contact holes, the peripheral contact plugs electrically connected to the source/drain impurity regions, respectively.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

Inventive concepts may relate to three-dimensionally arranged memory cells. For example, inventive concepts may relate to three-dimensionally arranged memory cells as disclosed in U.S. Pat. Nos. 7,679,133; 8,553,466; 8,654,587; 8,559,235; and US Pat. Pub. No. 2011/0233648, the entire contents of each of which are herein incorporated by reference.

FIG. 1 is a plan view of a three-dimensional semiconductor memory device according to some embodiments of the inventive concept.

FIGS. 2A to 2J are sectional views taken along line I-I′ of FIG. 1 to illustrate a method of fabricating a three-dimensional semiconductor memory device, according to some embodiments of the inventive concept.

FIGS. 3A to 3C are enlarged sectional views illustrating a portion (e.g., a portion ‘A’ of FIG. 2J) of a three-dimensional semiconductor memory device, according to some embodiments of the inventive concept.

FIGS. 4A and 4B are enlarged sectional views illustrating a portion (e.g., a portion ‘B’ of FIG. 2J) of a three-dimensional semiconductor memory device, according to some embodiments of the inventive concept.

FIG. 5 is an enlarged sectional view illustrating a portion (e.g., a portion ‘C’ of FIG. 2J) of a three-dimensional semiconductor memory device, according to some embodiments of the inventive concept.

FIGS. 6A and 6B are plan views illustrating a peripheral circuit region of a three-dimensional semiconductor memory device according to various embodiments of the inventive concept.

FIGS. 7A to 7H are sectional views illustrating a method of fabricating a three-dimensional semiconductor memory device according to various embodiments of the inventive concept.

FIGS. 8A to 8I are sectional views illustrating a method of fabricating a three-dimensional semiconductor memory device according to various embodiments of the inventive concept.

FIG. 9 is a sectional view of a three-dimensional semiconductor memory device according to various embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown.

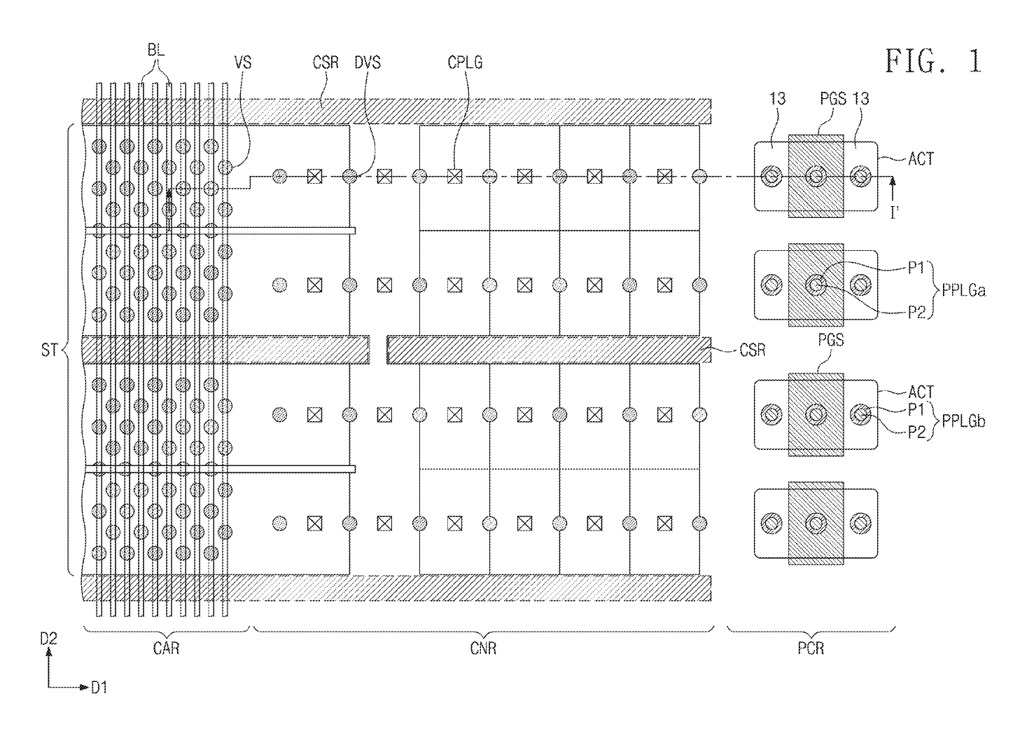

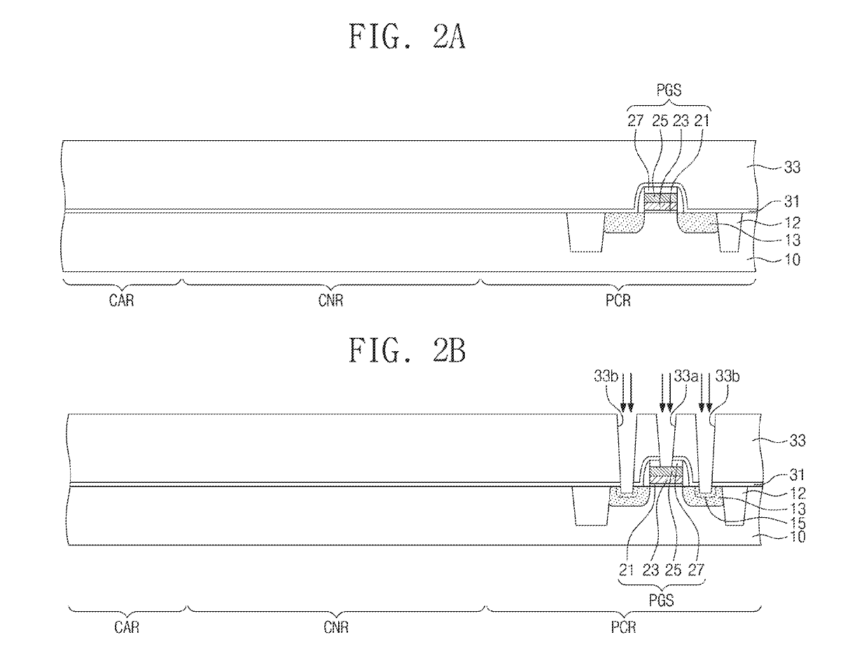

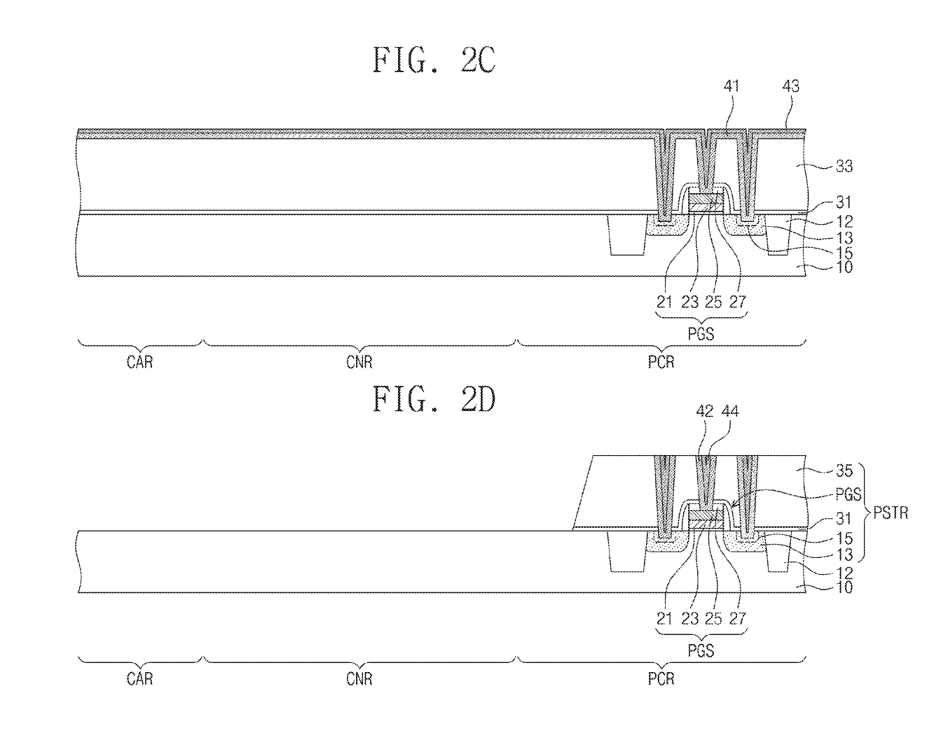

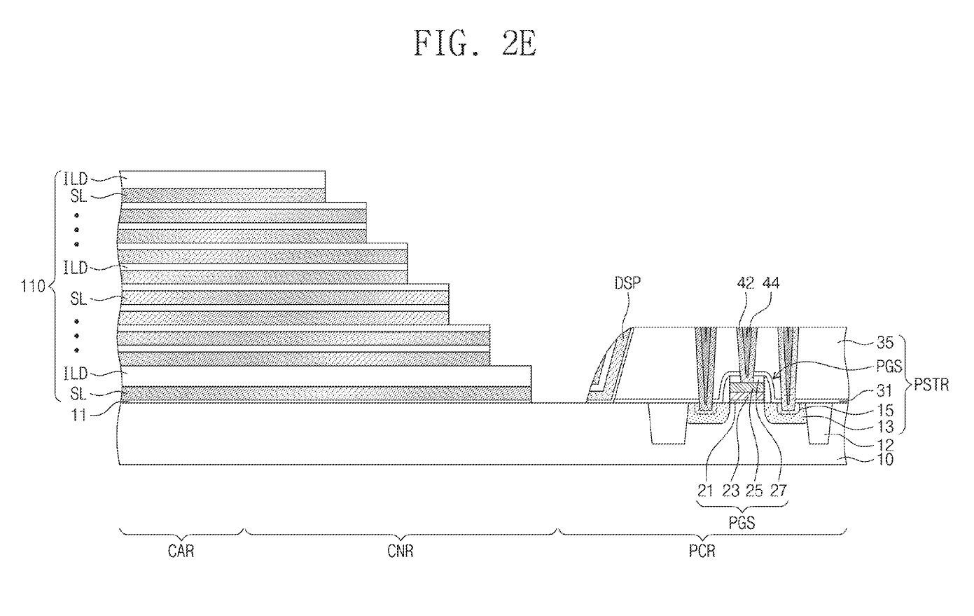

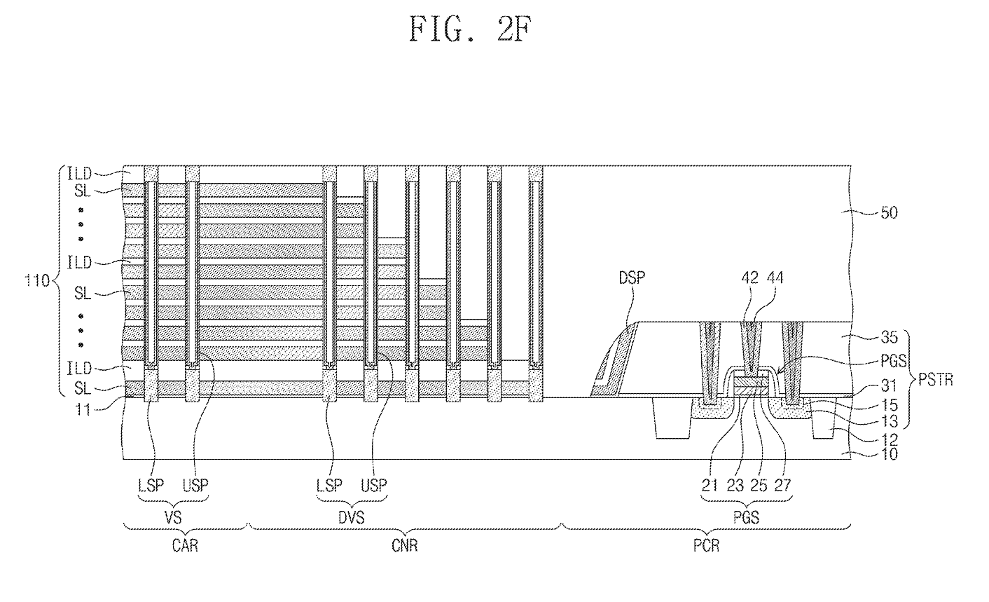

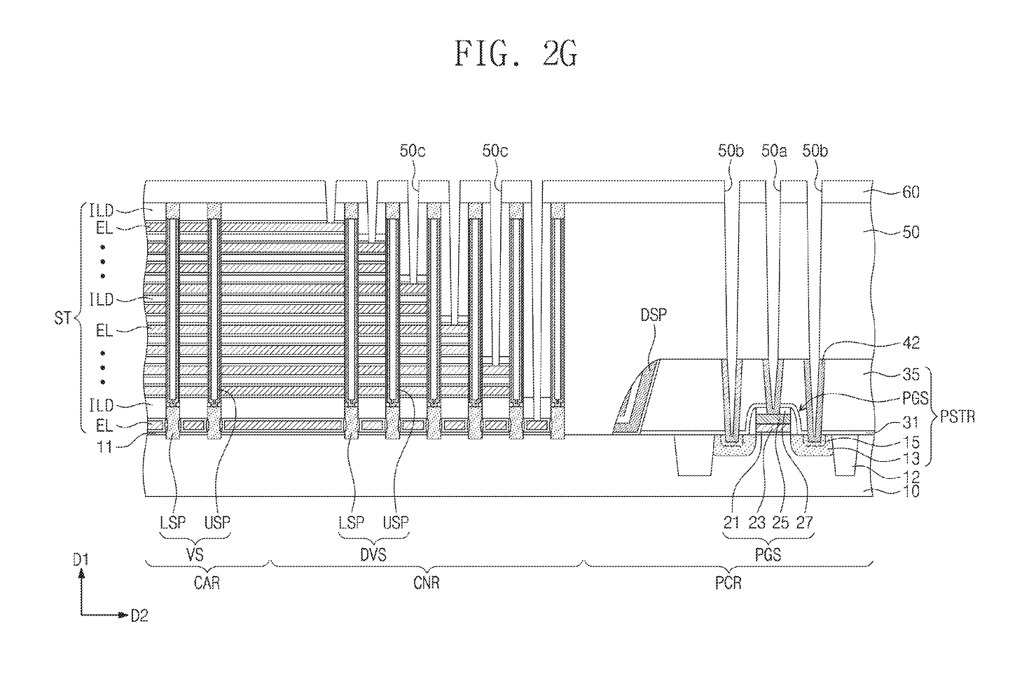

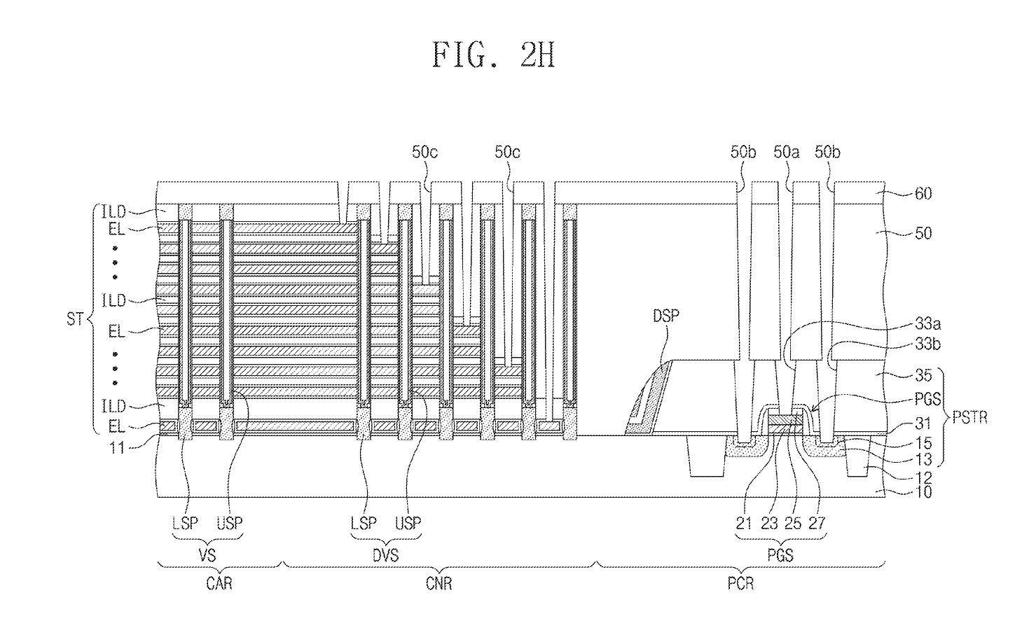

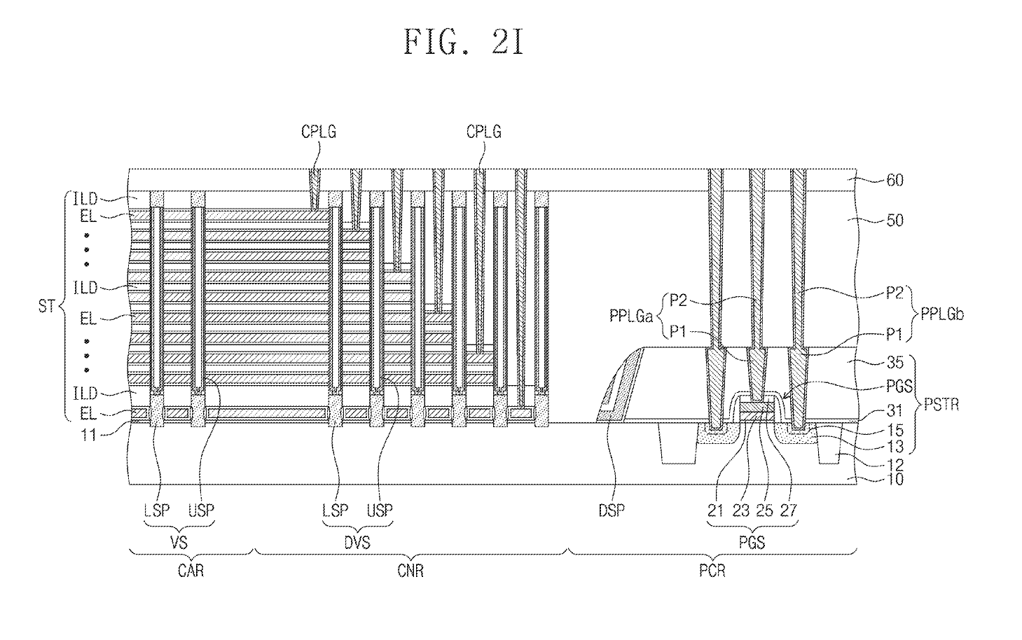

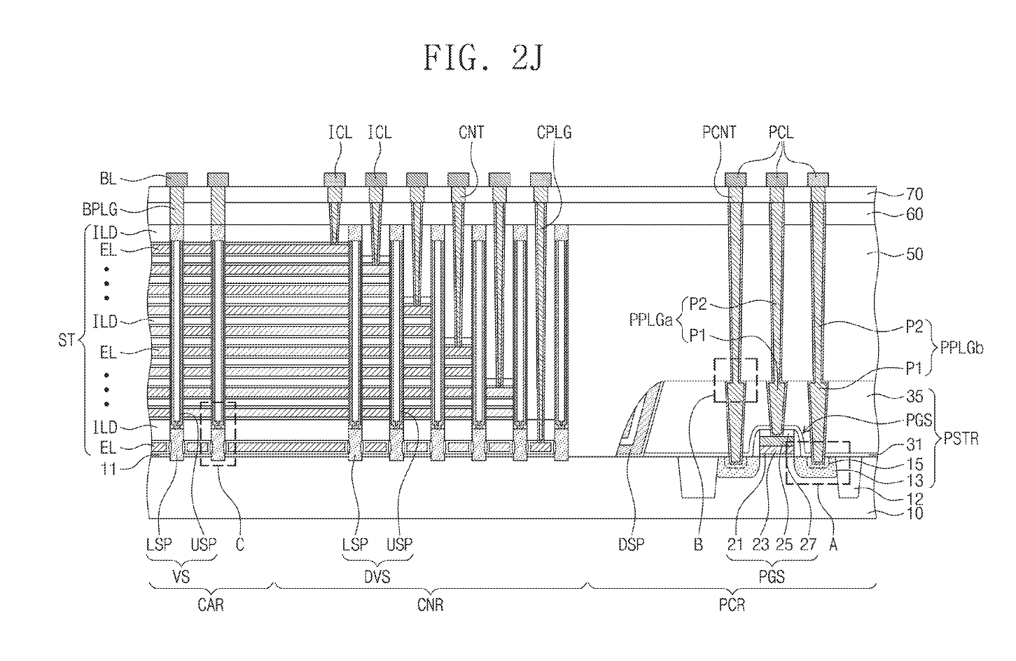

FIG. 1 is a plan view of a three-dimensional semiconductor memory device according to some embodiments of the inventive concept. FIGS. 2A to 2J are sectional views taken along line I-I′ of FIG. 1 to illustrate a method of fabricating a three-dimensional semiconductor memory device, according to some embodiments of the inventive concept.

Referring to FIGS. 1 and 2A, a substrate 10 may include a cell array region CAR, a connection region CNR, and a peripheral circuit region PCR. The connection region CNR may be located between the cell array region CAR and the peripheral circuit region PCR.

The substrate 10 may be formed of or include a material having a semiconductor property (e.g., a silicon wafer), an insulating material (e.g., a glass substrate), or a semiconductor or conductor material covered with an insulating material. For example, the substrate 10 may be or may include a silicon wafer having a first conductivity.

Peripheral logic circuits for writing or reading data to or from memory cells may be, e.g. may be formed, on the peripheral circuit region PCR of the substrate 10. The peripheral logic circuits may include row and column decoders, a page buffer, and/or control circuits. For example, the peripheral logic circuits may include NMOS and PMOS transistors, resistors, and capacitors, which are electrically connected to the memory cells.

For example, a device isolation layer 12 may be formed in the peripheral circuit region PCR of the substrate 10 to define an active region ACT. A peripheral gate stack PGS may be formed on the peripheral circuit region PCR of the substrate 10 to cross the active region ACT.

The peripheral gate stack PGS may include a peripheral gate insulating layer 21, a doped poly-silicon layer 23, a gate metal layer 25, and a hard mask layer 27, which are sequentially stacked on the substrate 10. The peripheral gate insulating layer 21 may be or may include a silicon oxide layer. The silicon oxide layer may be formed by a thermal oxidation process. The silicon oxide layer may be formed by an in-situ steam generation process. Spacers may be formed on both side surfaces of the peripheral gate stack PGS, and source/drain impurity regions 13 may be formed by doping the active region ACT at both sides of the peripheral gate stack PGS with first impurities. The first impurities may be elements selected from group III of the periodic table, e.g. boron. The first impurities may be elements selected from group V of the periodic table, e.g. phosphorus or arsenic. The source/drain impurity regions 13 may be formed with an ion-implantation process. For example, the source/drain impurity regions 13 may be formed with a high-current ion-implantation process. For example, the source/drain impurity regions 13 may be formed with a plasma-assisted doping process. However, inventive concepts are not limited thereto.

After the formation of the peripheral logic circuits, an etch stop layer 31 and a peripheral insulating layer 33 may be formed, e.g. sequentially formed, on the substrate 10. The etch stop layer 31 may be deposited to conformally cover the peripheral logic circuits. The peripheral insulating layer 33 may include a plurality of insulating layers (for example, including at least one of a silicon oxide layer, a silicon nitride layer, a silicon oxynitride layer, or low-k dielectric layers).

Referring to FIGS. 1 and 2B, a first lower contact hole 33a may be formed exposing the peripheral gate stack PGS, and second lower contact holes 33b may be formed exposing the source/drain impurity regions 13, respectively.

The first and second lower contact holes 33a and 33b may be formed by forming a mask pattern (not shown) on the peripheral insulating layer 33 and then etching, e.g. anisotropically etching, the peripheral insulating layer 33. The first lower contact holes 33a may be formed exposing the gate metal layer 25 of the peripheral gate stack PGS, and the second lower contact holes 33b may be formed partially exposing the source/drain impurity regions 13.

Each of the first and second lower contact holes 33a and 33b may have a lower width that is smaller than an upper width. When the second lower contact holes 33b are formed, the top surface of the substrate 10 may be recessed by the anisotropic etching process.

In some embodiments, after the formation of the first and second lower contact holes 33a and 33b, dummy impurity regions 15 may be formed by doping the source/drain impurity regions 13 with second impurities. The second impurities may be of a different kind from that of the first impurities and may include, for example, carbon (C), nitrogen (N), or fluorine (F).

The dummy impurity regions 15 may be co-doped with the second impurities and the first impurities. A concentration of the second impurities in the dummy impurity region 15 may be smaller than that of the first impurities in the source/drain impurity regions 13. For example, the concentration of the second impurities in the dummy impurity region 14 may be smaller by one, or several, orders of magnitude. A dopant concentration of the second impurities may be between about 1e14 atoms/cm3 to about 1e16 atoms/cm3.

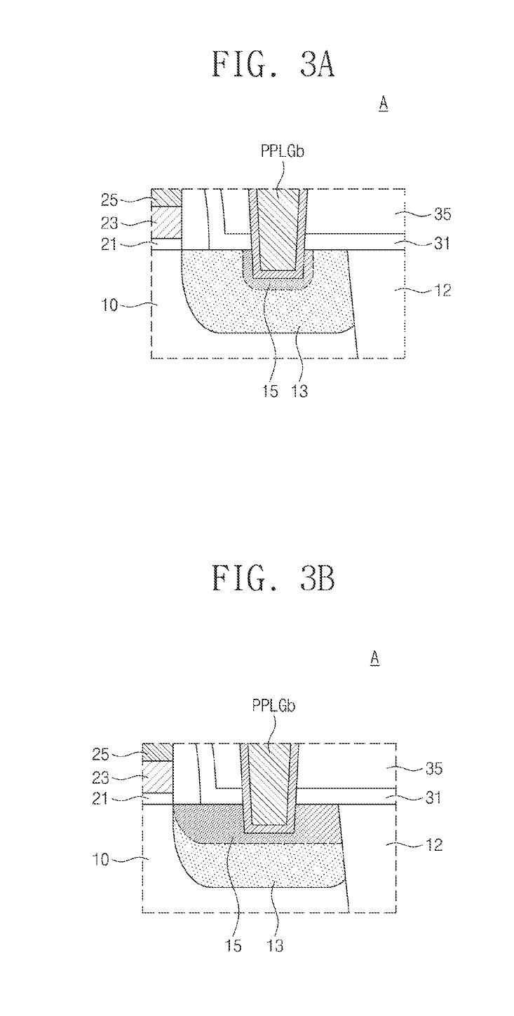

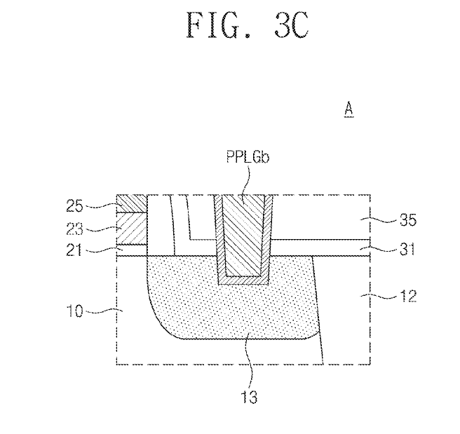

The formation of the dummy impurity regions 15 may include injecting second impurities into a portion of the substrate 10 exposed by the second lower contact holes 33b. The dummy impurity regions 15 may be formed to have a depth shallower than that of the source/drain impurity regions 13, as shown in FIG. 3A. In other words, the dummy impurity regions 15 may be formed around the second lower contact holes 33b.

In certain embodiments, as shown in FIG. 3B, the dummy impurity regions 15 may be formed after the formation of the source/drain impurity regions 13 and before the formation of the peripheral insulating layer 33. The dummy impurity regions 15 may be formed by injecting the first impurities into the substrate 10 using an ion implantation process, forming the source/drain impurity regions 13, and then shallowly implanting the second impurities into the source/drain impurity regions 13 using an ion implantation mask, which is the same as that for the source/drain impurity regions 13. The second impurities may be implanted into the dummy impurity regions 15 with a medium-current or low current implantation; however, inventive concepts are not limited thereto.

Alternatively, as shown in FIG. 3C, the dummy impurity regions 15 may be formed together with the source/drain impurity regions 13. For example, when the source/drain impurity regions 13 are formed, the first and second impurities may be together injected into the substrate 10.

Referring to FIGS. 1 and 2C, a sacrificial plug layer 41 and a sacrificial gap-filling layer 43 may be sequentially formed, to a uniform thickness, on the peripheral insulating layer 33 with the first and second lower contact holes 33a and 33b.

The sacrificial plug layer 41 may be formed of a material having an etch selectivity with respect to the peripheral insulating layer 33, and the sacrificial gap-filling layer 43 may be formed of a material having an etch selectivity with respect to the sacrificial plug layer 41. The sacrificial plug layer 41 may be formed of or include, for example, a poly-silicon layer, a silicon layer, a germanium layer, or a silicon germanium layer. The sacrificial gap-filling layer 43 may be formed of or include, for example, a silicon oxide layer.

The sacrificial plug layer 41 may be deposited using a deposition process having a good step coverage property (e.g., using chemical vapor deposition (CVD) or atomic layer deposition (ALD) process). Here, a thickness of the sacrificial plug layer 41 may be less than about half an upper width of the first and second lower contact holes 33a and 33b. Thus, the sacrificial plug layer 41 may uniformly cover inner surfaces of the first and second lower contact holes 33a and 33b and may partially fill the first and second lower contact holes 33a and 33b. In some embodiments, the sacrificial plug layer 41 may be in direct contact with the dummy impurity region 15. In the case where the dummy impurity region 15 is not formed, the sacrificial plug layer 41 may be in direct contact with the source/drain impurity regions 13.

The sacrificial gap-filling layer 43 may be deposited on the sacrificial plug layer 41. In some embodiments, the sacrificial gap-filling layer 43 may be formed filling the first and second lower contact holes 33a and 33b covered with the sacrificial plug layer 41.

Referring to FIGS. 1 and 2D, after the formation of the sacrificial plug layer 41 and the sacrificial gap-filling layer 43, a planarization process may be performed exposing the top surface of the peripheral insulating layer 33. Accordingly, a sacrificial plug 42 and a sacrificial gapfill pattern 44 may be formed in each of the first and second lower contact holes 33a and 33b.

Thereafter, the peripheral insulating layer 33 may be patterned to form a peripheral insulating pattern 35 exposing the cell array region CAR and the connection region CNR of the substrate 10. As a result of the formation of the peripheral insulating pattern 35, a peripheral logic structure PSTR may be formed on the peripheral circuit region PCR of the substrate 10, and here, the peripheral logic structure PSTR may include the peripheral gate stack PGS, the source/drain impurity regions 13, and the peripheral insulating pattern 35.

Referring to FIGS. 1 and 2E, after the formation of the peripheral insulating pattern 35, a mold structure 110 may be formed on the cell array region CAR and the connection region CNR of the substrate 10. The mold structure 110 may include sacrificial layers SL and insulating layers ILD, which are stacked, e.g. alternatingly stacked, on the substrate 10.

In the mold structure 110, the sacrificial layers SL may be formed of or include a material, which can be etched with a high etch selectivity with respect to the insulating layers ILD. As an example, the sacrificial layers SL may be formed of an insulating material different from the insulating layers ILD. For example, the sacrificial layers SL may be formed of a silicon nitride layer, and the insulating layers ILD may be formed of a silicon oxide layer. The sacrificial layers SL may have substantially the same thickness, and at least one of the insulating layers ILD may have a thickness different from the others.

For example, the formation of the mold structure 110 may include forming a layered structure, in which the sacrificial and insulating layers SL and ILD are alternatingly stacked, on the substrate 10, and performing a trimming process on the layered structure. Here, the trimming process may include steps of forming a mask pattern (not shown) covering the layered structure on the cell array region CAR and the connection region CNR, etching the layered structure using the mask pattern as an etch mask, etching the mask pattern to reduce a planar area of the mask pattern, and removing the mask pattern. The steps of etching the layered structure and the mask pattern may be repeated several times, before the step of removing the mask pattern.

As a result of the trimming process, the mold structure 110 may extend from the cell array region CAR to the connection region CNR and may have a staircase structure on the connection region CNR. For example, the mold structure 110 may have a staircase structure, whose height decreases in a stepwise manner in a direction toward the peripheral circuit region PCR. The mold structure 110 may have a vertical height greater than that of the peripheral structure. For example, the vertical height of the mold structure 110 may be greater than or equal to about 2 times the height of the peripheral structure.

Furthermore, during the trimming process of forming the mold structure 110, a dummy spacer DSP may be formed on a side surface of the peripheral insulating pattern 35. The dummy spacer DSP may be or may include remaining portions of the sacrificial and insulating layers SL and ILD, which are not etched by an anisotropic etching process.

Referring to FIGS. 1 and 2F, an upper planarized insulating layer 50 may be formed covering the substrate 10 provided with the mold structure 110. The upper planarized insulating layer 50 may be extended covering not only the mold structure 110 but also the peripheral structure, and may have a substantially flat top surface. The upper planarized insulating layer 50 may be formed of a material having an etch selectivity with respect to the sacrificial layers SL.

After the formation of the upper planarized insulating layer 50, vertical structures VS may be formed on the cell array region CAR, penetrating the mold structure 110. The vertical structures VS may be arranged in a specific direction or in a zigzag shape, when viewed in a plan view.

In addition, during the formation of the vertical structures VS, dummy vertical structures DVS may be formed on the connection region CNR partially penetrating the mold structure 110. The dummy vertical structures DVS may have substantially the same structure as the vertical structures VS and may be formed penetrating end portions of the sacrificial layers SL.

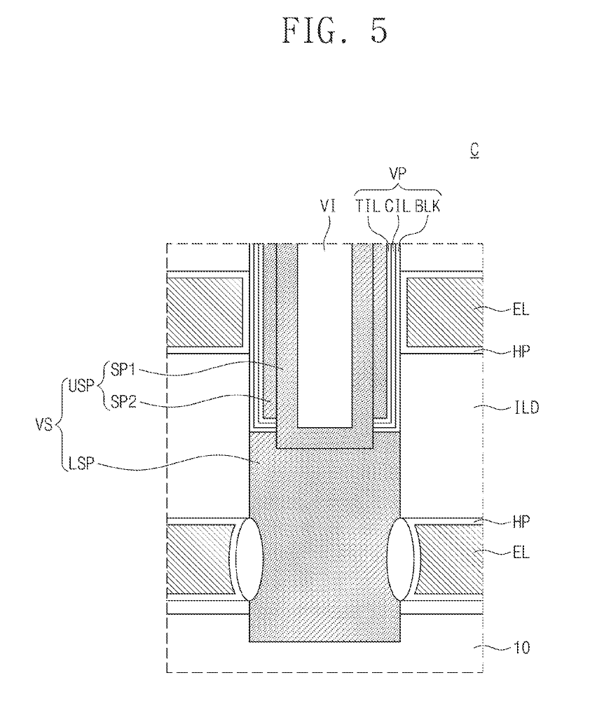

The formation of the vertical structures VS and the dummy vertical structures DVS may include forming vertical holes penetrating the mold structure 110 and expose the substrate 10 and forming a lower semiconductor pattern LSP and an upper semiconductor pattern USP in each of the vertical holes. Here, semiconductor materials for the lower and upper semiconductor patterns LSP and USP may have crystal structures different from each other. In some embodiments, the lower semiconductor pattern LSP may have a pillar shape, and a top surface of the lower semiconductor pattern LSP may be located below top surfaces of the sacrificial plugs 42 on the peripheral circuit region PCR. In addition, a conductive pad D may be formed in a top portion of each of the upper semiconductor patterns USP. The conductive pad D may be an impurity region doped with impurities or may be formed of a conductive material. The vertical structures VS and the dummy vertical structures DVS will be described in more detail with reference to FIG. 5.

Referring to FIGS. 1 and 2G, a first interlayered insulating layer 60 may be formed on the upper planarized insulating layer 50 and may cover top surfaces of the vertical structures VS and the dummy vertical structures DVS.

After the formation of the first interlayered insulating layer 60, a replacement process may be performed replacing the sacrificial layers SL with electrodes EL. As a result of the replacement process, an electrode structure ST including the electrodes EL and the insulating layers ILD, which are alternatingly stacked on the substrate 10 may be formed. The electrode structure ST may have a staircase structure on the connection region CNR.

The replacement process may include forming trenches, which penetrate the first interlayered insulating layer 60, the upper planarized insulating layer 50, and the mold structure 110 and expose the substrate 10, on the cell array region CAR and the connection region CNR. The replacement process may include removing the sacrificial layers SL exposed by the trenches to form gate regions between the insulating layers ILD, and forming the electrodes EL in the gate regions, respectively.

Here, the trenches may extend in a first direction D1 and may be spaced apart from each other in a second direction D2 crossing the first direction D1. In some embodiments, the trenches may have at least two different lengths and may be formed to allow the mold structure 110 to have, for example, a substantially ‘H’-shaped structure in a plan view. The trenches may be spaced apart from the vertical structures VS and may be formed exposing side surfaces of the sacrificial and insulating layers SL and ILD.

The formation of the gate regions may include isotropically etching the sacrificial layers SL using an etch recipe that is selected to have an etch selectivity with respect to the upper planarized insulating layer 50, the insulating layers ILD, the vertical structures VS, and the substrate 10.

The formation of the electrodes EL may include sequentially depositing a barrier metal layer and a metal layer on the mold structure 110 with the gate regions, and then, anisotropically etching the barrier metal layer and the metal layer that are deposited on an inner surface of the trench. The barrier metal layer may be formed of a metal nitride layer (e.g., TiN, TaN, or WN). The metal layer may be formed of a metal material (e.g., W, Al, Ti, Ta, Co, or Cu).

In some embodiments, before the formation of the electrodes EL, a horizontal insulating pattern HP may be formed to conformally cover inner surfaces of the gate regions, as shown in FIG. 5. The horizontal insulating pattern HP may be used as a part of a data storing layer of a NAND FLASH memory transistor. The horizontal insulating pattern HP may be or may include one of high-k dielectric materials (e.g., aluminum oxide and hafnium oxide). In addition, before the formation of the horizontal insulating pattern HP, a thermal oxide layer may be formed on a side surface of the lower semiconductor pattern LSP.

Furthermore, common source regions CSR may be formed in the substrate 10 exposed by the trenches. The common source regions CSR may extend in the first direction D1 and parallel to each other and may be spaced apart from each other in the second direction D2. The common source regions CSR may be formed by doping the substrate 10 with impurities that are of a different type from that of the substrate 10. The common source regions CSR may contain n-type impurities (e.g., arsenic (As) or phosphorus (P)).

Next, referring to FIGS. 1 and 2G, after the formation of the electrode structure ST, the first interlayered insulating layer 60 and the upper planarized insulating layer 50 may be patterned to form cell contact holes 50c on the connection region CNR and upper contact holes 50a and 50b on the peripheral circuit region PCR.

The formation of the cell contact holes 50c and the upper contact holes 50a and 50b may include forming a mask pattern (not shown) on the first interlayered insulating layer 60 and anisotropically etching the first interlayered insulating layer 60 and the upper planarized insulating layer 50. In some embodiments, the cell contact holes 50c and the upper contact holes 50a and 50b may be formed at the same time, but inventive concepts are not limited thereto. In certain embodiments, some of the cell contact holes 50c may be formed, and then, the upper contact holes 50a and 50b may be formed together with the others of the cell contact holes 50c. In certain embodiments, the upper contact holes 50a and 50b may be formed together with some of the contact holes 50c, and then the others of the contact holes 50c may be formed.

In some embodiments, the cell contact holes 50c may be formed exposing end portions of the electrodes EL, respectively, on the connection region CNR. The cell contact holes 50c may have vertical lengths different from each other, where the vertical lengths are lengths measured in a direction normal to the top surface of the substrate 10.

In some embodiments, the upper planarized insulating layer 50 may include the same material as the sacrificial gapfill pattern 44 and may be etched together with the sacrificial gapfill pattern 44, when the upper contact holes 50a and 50b are formed. In this case, the upper contact holes 50a and 50b may expose the sacrificial plugs 42.

In some embodiments, the upper contact holes 50a and 50b may have vertical depths that are less than the largest value of vertical depths of the cell contact holes 50c. In addition, the vertical depths of the upper contact holes 50a and 50b may be greater than vertical depths of the lower contact holes (e.g., see 33a and 33b of FIG. 2B). For example, aspect ratios of the upper contact holes 50a and 50b may be greater than those of the lower contact holes (e.g., see 33a and 33b of FIG. 2B). Each of the upper contact holes 50a and 50b may have an upper width that is less than a lower width, even when an anisotropic etching process is used to form the upper contact holes 50a and 50b. The lower widths of the upper contact holes 50a and 50b may be smaller than upper widths of the lower contact holes 33a and 33b. In addition, the lower width of each of the upper contact holes 50a and 50b may be larger than an upper width of the sacrificial gapfill pattern 44.

Referring to FIGS. 1 and 2H, the sacrificial plugs 42 exposed by the upper contact holes 50a and 50b may be removed exposing inner surfaces of the lower contact holes 33a and 33b. In the case where the sacrificial plugs 42 are removed, the lower contact holes 33a and 33b may be connected to the upper contact holes 50a and 50b, respectively.

In some embodiments, the removal of the sacrificial plugs 42 may include anisotropically or isotropically etching the sacrificial plugs 42 using an etch recipe, which is selected to have an etch selectivity with respect to the peripheral insulating pattern 35.

As a result of the removal of the sacrificial plugs 42, the metal layer of the peripheral gate stack PGS may be exposed through the first lower contact holes 33a, and the dummy impurity region 15 may be exposed through the second lower contact holes 33b. The dummy impurity region 15 may prevent, or help to reduce the likelihood of, the source/drain impurity regions 13 from being damaged by an etching gas or etchant, which is used to remove the sacrificial plugs 42. For example, the sacrificial plugs 42 may be formed of or include a poly-silicon layer, and the dummy impurity region 15 may suppress and prevent, or help to reduce the likelihood of, the source/drain impurity regions 13 in the substrate 10 from being unnecessarily etched, when the sacrificial plugs 42 are etched.

Referring to FIGS. 1 and 2I, cell contact plugs CPLG may be formed in the cell contact holes 50c and on the connection region CNR, and peripheral contact plugs PPLGa and PPLGb may be formed in the lower and upper contact holes 33a, 33b, 50a, and 50b and on the peripheral circuit region PCR.

The formation of the cell contact plugs CPLG and the peripheral contact plugs PPLGa and PPLGb may include sequentially depositing a barrier metal layer and a metal layer in the upper and lower contact holes 50a, 50b, 33a, and 33b and the cell contact holes 50c, and then performing a planarization process exposing the top surface of the first interlayered insulating layer 60. Here, the barrier metal layer may be formed of or include at least one metal nitrides (e.g., TiN, TaN, or WN). The metal layer may be formed of or include at least one metal materials (e.g., W, Al, Ti, Ta, Co, or Cu). In some example embodiments, the cell contact plugs CPLG and the peripheral contact plugs PPLGa and PPLGb may be formed at the same time, and in this case, the cell contact plugs CPLG may have top surfaces that are substantially coplanar with those of the peripheral contact plugs PPLGa and PPLGb. In addition, since the upper and lower contact holes 50a, 50b, 33a, and 33b are filled at a time with the metal layer, each of the peripheral contact plugs PPLGa and PPLGb may penetrate the first interlayered insulating layer 60, the upper planarized insulating layer 50, and the peripheral insulating pattern 35, without an interface.

The cell contact plugs CPLG may be formed penetrating the first interlayered insulating layer 60 and the upper planarized insulating layer 50 and may be coupled to end portions of the electrodes EL, respectively. The cell contact plugs CPLG may be formed having a vertical length decreasing in a direction toward the cell array region CAR.

The peripheral contact plugs PPLGa and PPLGb may include a first peripheral contact plug PPLGa, which is in contact with the gate metal layer 25 of the peripheral gate stack PGS, and second peripheral contact plugs PPLGb, which are electrically connected to the source/drain impurity regions 13. Here, bottom surfaces of the second peripheral contact plugs PPLGb may be located below the top surface of the substrate 10 and may be in contact with the dummy impurity regions 15.

The first and second peripheral contact plugs PPLGa and PPLGb may, or may be provided to. continuously penetrate the first interlayered insulating layer 60, the upper planarized insulating layer 50, and the peripheral insulating pattern 35 and may have a varying width near an interface between the peripheral insulating pattern 35 and the upper planarized insulating layer 50. For example, each of the first and second peripheral contact plugs PPLGa and PPLGb may include a lower portion P1, penetrating the peripheral insulating pattern 35, and an upper portion P2, which is continuously extended from the lower portion P1 penetrating the upper planarized insulating layer 50 and the first interlayered insulating layer 60. When measured vertically from the top surface of the substrate 10, a vertical length of the upper portion P2 may be greater than that of the lower portion P1. Each of the lower and upper portions P1 and P2 may have a decreasing width in a downward direction, and an upper width of the lower portion P1 may be greater than a lower width of the upper portion P2.

Referring to FIGS. 1 and 2J, a second interlayered insulating layer 70 may be formed on the first interlayered insulating layer 60 covering the cell contact plugs CPLG and the first and second peripheral contact plugs PPLGa and PPLGb.

Bit line contact plugs BPLG, connection contact plugs CNT, and peripheral connection contact plugs PCNT may be formed in the second interlayered insulating layer 70.

The bit line contact plugs BPLG may be provided penetrating the second interlayered insulating layer 70 on the cell array region CAR and may be coupled to the vertical structures VS, respectively. The connection contact plugs CNT may penetrating the second interlayered insulating layer 70 on the connection region CNR and may be coupled to the cell contact plugs CPLG, respectively. The peripheral connection contact plugs PCNT may be provided penetrating the second interlayered insulating layer 70 on the peripheral circuit region PCR and may be coupled to the first and second peripheral contact plugs PPLGa and PPLGb, respectively.

Next, bit lines BL, interconnection lines ICL, and peripheral connection lines PCL may be formed on the second interlayered insulating layer 70. The bit lines BL may extend in the second direction D2 on the cell array region CAR and may be connected to the bit line contact plugs BPLG. The interconnection lines ICL may be provided on the connection region CNR and may be connected to the connection contact plugs CNT. The peripheral connection lines PCL may be provided on the peripheral circuit region PCR and may be connected to the peripheral connection contact plugs PCNT.

FIGS. 3A to 3C are enlarged sectional views illustrating a portion (e.g., a portion ‘A’ of FIG. 2J) of a three-dimensional semiconductor memory device, according to some embodiments of the inventive concept.

Referring to FIG. 3A, the dummy impurity region 15 may be locally formed in the source/drain impurity region 13. For example, the dummy impurity region 15 may have a width less than a width of the source/drain impurity region 13. The second peripheral contact plug PPLGb may have a bottom surface in direct contact with the dummy impurity region 15, and spaced apart from the source/drain impurity region 13. The dummy impurity region 15 may enclose a portion of the second peripheral contact plug PPLGb inserted into the substrate 10.

Referring to FIG. 3B, the dummy impurity region 15 may be formed in an upper region of the source/drain impurity region 13. For example, the dummy impurity region 15 may have a depth less than that of the source/drain impurity region 13. The second peripheral contact plug PPLGb may have a bottom surface that is located in the dummy impurity region 15 and spaced apart from a bottom surface of the source/drain impurity region 13.

In the embodiments of FIG. 3C, the dummy impurity region 15 may be omitted. In this case, the second peripheral contact plug PPLGb may be in direct contact with the source/drain impurity region 13.

In certain embodiments, the second peripheral contact plug PPLGb may be in direct contact with the source/drain impurity region 13, and here, the source/drain impurity region 13 may be co-doped with the first impurities (e.g., one of boron (B) or phosphorus (P)) and the second impurities (e.g., at least one of carbon (C), nitrogen (N), or fluorine (F)).

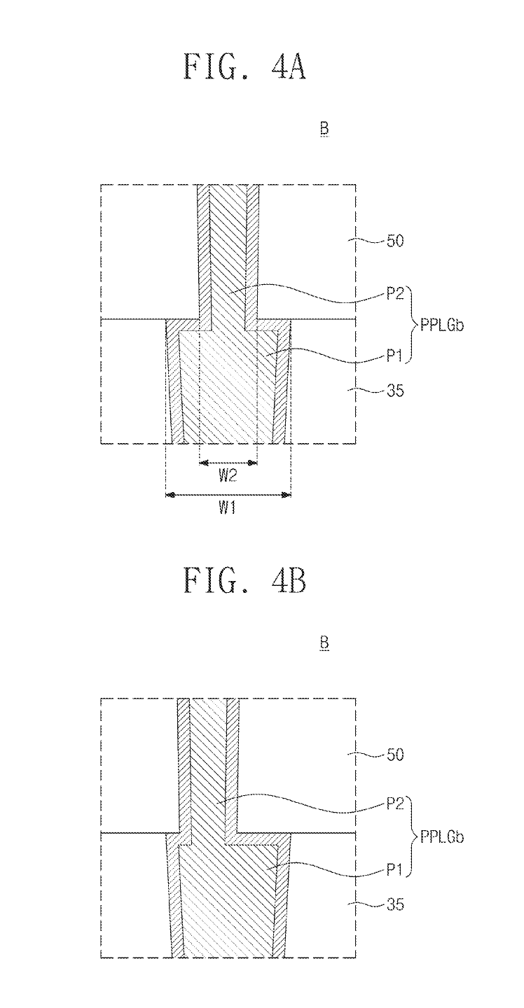

FIGS. 4A and 4B are enlarged sectional views illustrating a portion (e.g., a portion ‘B’ of FIG. 2J) of a three-dimensional semiconductor memory device, according to some embodiments of the inventive concept.

Referring to FIGS. 4A and 4B, each of the lower and upper portions P1 and P2 of the second peripheral contact plug PPLGb may have a width decreasing in a downward direction. For example, in the second peripheral contact plug PPLGb, an upper width W1 of the lower portion P1 may be greater than a lower width W2 of the upper portion P2. Thus, the second peripheral contact plug PPLGb may have an inflection point at a level between the peripheral insulating pattern 35 and the upper planarized insulating layer 50. In addition, the upper planarized insulating layer 50 may have a bottom surface directly covering a portion of a top surface of the lower portion P1 of the second peripheral contact plug PPLGb.

As shown in FIG. 4A, the upper portion P2 of the second peripheral contact plug PPLGb may be aligned to the lower portion P1, when viewed in a plan view. In certain embodiments, as shown in FIG. 4B, the upper portion P2 of the second peripheral contact plug PPLGb may be offset from the lower portion P1. In other words, the upper portion P2 of the second peripheral contact plug PPLGb may continuously extend from the lower portion P1, but a center of the upper portion P2 may be misaligned from that of the lower portion P1.

FIG. 5 is an enlarged sectional view illustrating a portion (e.g., a portion ‘C’ of FIG. 2J) of a three-dimensional semiconductor memory device, according to some embodiments of inventive concepts.

Referring to FIG. 5, each of the vertical structures VS may include the lower semiconductor pattern LSP and the upper semiconductor pattern USP.

The lower semiconductor pattern LSP may be formed by a selective epitaxial growth (SEG) process, in which the substrate 10 exposed by the vertical holes is used as a seed layer. Accordingly, the lower semiconductor pattern LSP may be a pillar-shaped structure filling a lower region of the vertical hole. The lower semiconductor pattern LSP may be formed to have a single- or poly-crystalline structure, but inventive concepts may not be limited thereto. The lower semiconductor pattern LSP may be formed of, for example, carbon nano structures, organic semiconductor materials, and/or compound semiconductor materials.

The upper semiconductor pattern USP may be formed in the vertical hole provided with the lower semiconductor pattern LSP. The upper semiconductor pattern USP may be in contact with the lower semiconductor pattern LSP.

In detail, as shown in FIG. 5, the upper semiconductor pattern USP may include a first semiconductor pattern SP1 and a second semiconductor pattern SP2. The first semiconductor pattern SP1 may be coupled to the lower semiconductor pattern LSP and may have a pipe or macaroni shape with closed bottom and open top. An inner space of the first semiconductor pattern SP1 may be filled with an insulating gapfill pattern VI. In addition, the first semiconductor pattern SP1 may be in contact with an inner surface of the second semiconductor pattern SP2 and the top surface of the lower semiconductor pattern LSP. For example, the first semiconductor pattern SP1 may allow the second semiconductor pattern SP2 to be electrically connected to the lower semiconductor pattern LSP.

The upper semiconductor pattern USP may be formed of or include at least one of doped or intrinsic semiconductor materials (e.g., of silicon (Si), germanium (Ge), or compounds thereof). In addition, the upper semiconductor pattern USP may have one of single-crystalline, amorphous, and poly-crystalline structures.

In some embodiments, before the formation of the upper semiconductor pattern USP, a vertical insulating pattern VP may be formed in each of the vertical holes, as shown in FIG. 5. In other words, the vertical insulating pattern VP may be vertically extended from regions between the electrodes EL and the vertical structure VS to other regions between the insulating layer ILD and the vertical structure VS. In addition, the horizontal insulating pattern HP may be horizontally extended from regions between the electrodes EL and a first blocking insulating layer BLK1 to other regions toward top or bottom surfaces of the electrodes EL.

The vertical insulating pattern VP may include one or more layers. In some embodiments, the vertical insulating pattern VP may be used as a memory element of a NAND FLASH memory device and may include at least some of a tunnel insulating layer TIL, a charge storing layer CIL, and a blocking insulating layer BLK. For example, the charge storing layer CIL may be or may include a trap insulating layer, a floating gate electrode, or an insulating layer with conductive nano dots. In detail, the charge storing layer CIL may include at least one of a silicon nitride layer, a silicon oxynitride layer, a silicon-rich nitride layer, a nanocrystalline silicon layer, or a laminated trap layer. The tunnel insulating layer TIL may be formed of at least one of materials whose band gaps are greater than that of the charge storing layer CIL, and the blocking insulating layer BLK may be formed of a high-k dielectric material (e.g., aluminum oxide and hafnium oxide).

In certain embodiments, the vertical insulating pattern VP may be used as a memory element of a phase-change memory device or a variable resistance memory, and may include a phase-change or variable-resistance layer.

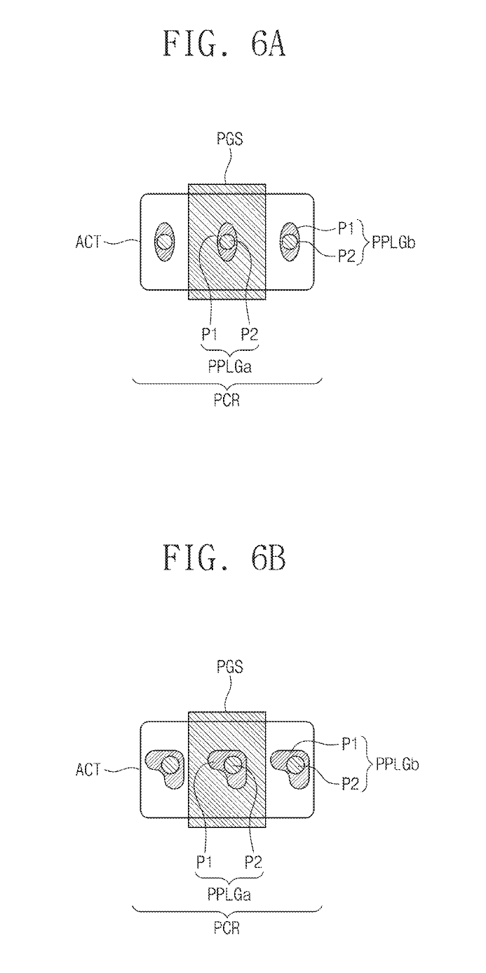

FIGS. 6A and 6B are plan views illustrating a peripheral circuit region of a three-dimensional semiconductor memory device according to various embodiments of the inventive concept.

For concise description, an element previously described with reference to FIGS. 2A to 2J may be identified by a similar or identical reference number without repeating an overlapping description thereof.

Referring to FIGS. 6A and 6B, each of the first and second peripheral contact plugs PPLGa and PPLGb on the peripheral circuit region PCR may include the lower portion P1 and the upper portion P2, as described above.

In the embodiments of FIG. 6A, in each of the first and second peripheral contact plugs PPLGa and PPLGb, a top surface of the lower portion P1 may have an elliptical shape, whose longitudinal axis is parallel to a specific direction. Accordingly, in each of the first and second peripheral contact plugs PPLGa and PPLGb, preventing, or reducing the likelihood of, the lower portion P1 from being misaligned from the upper portion P2 may be possible. Similarly, preventing or reducing the likelihood of the first and second peripheral contact plugs PPLGa and PPLGb from being cut between the peripheral insulating pattern 35 and the upper planarized insulating layer 50 may be possible.

In each of the first and second peripheral contact plugs PPLGa and PPLGb, the top surface of the lower portion P1 may have a polygonal shape, as shown in FIG. 6B. For example, in each of the first and second peripheral contact plugs PPLGa and PPLGb, the top surface of the lower portion P1 may include a first portion extending in a first direction and a second portion extending in a second direction.

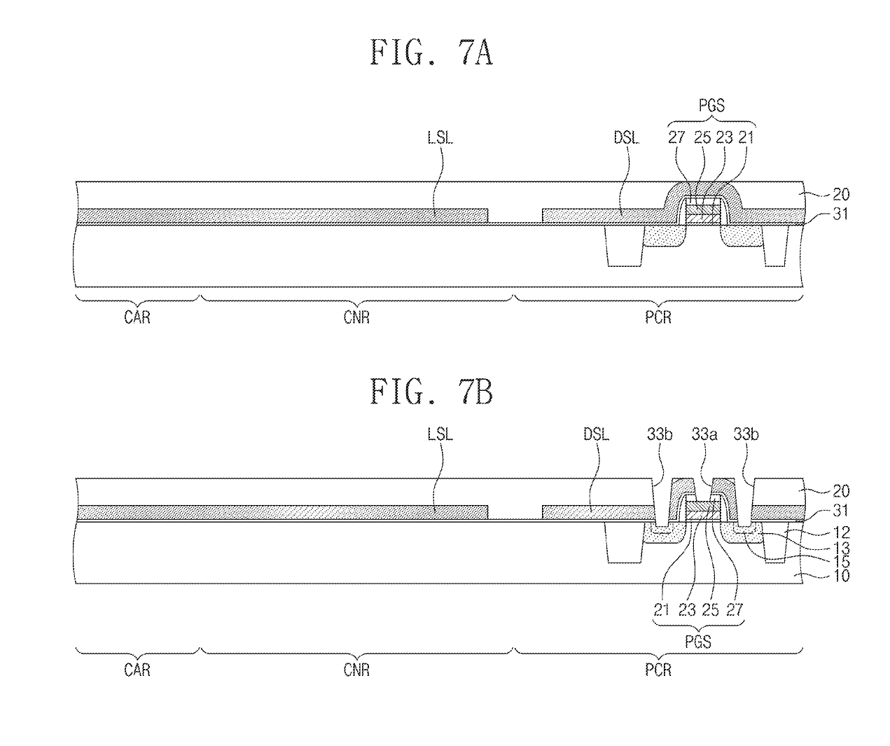

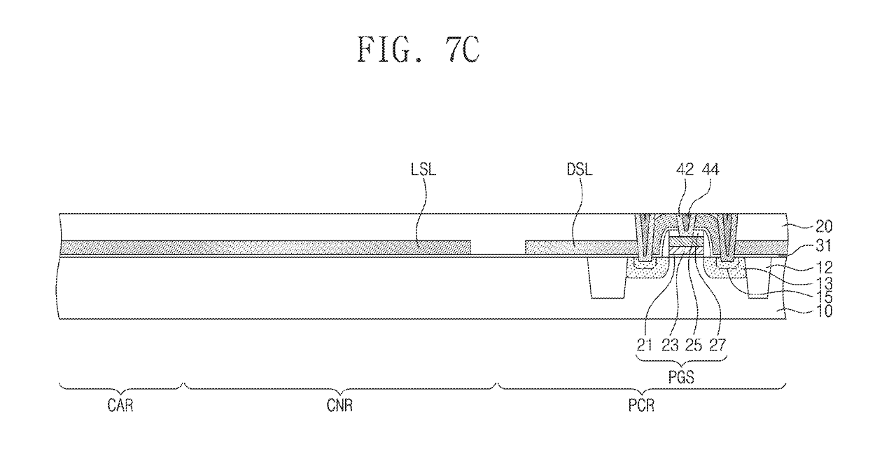

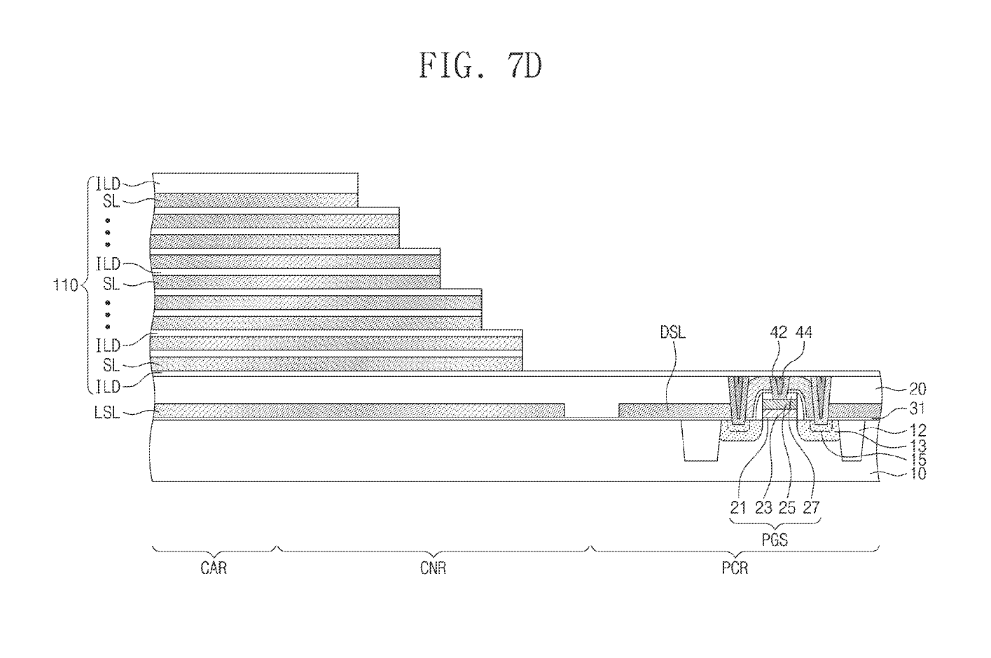

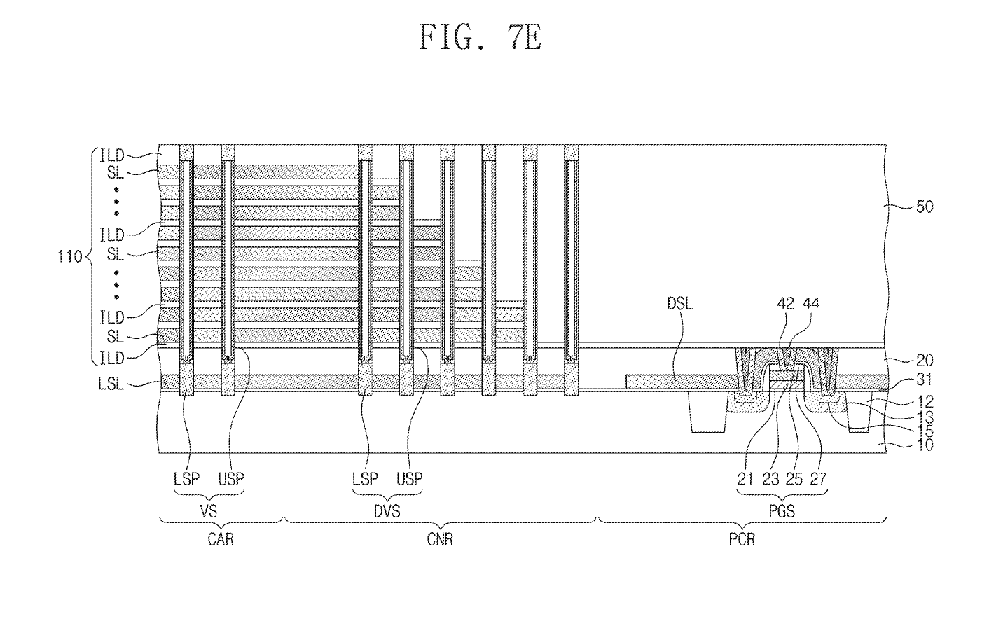

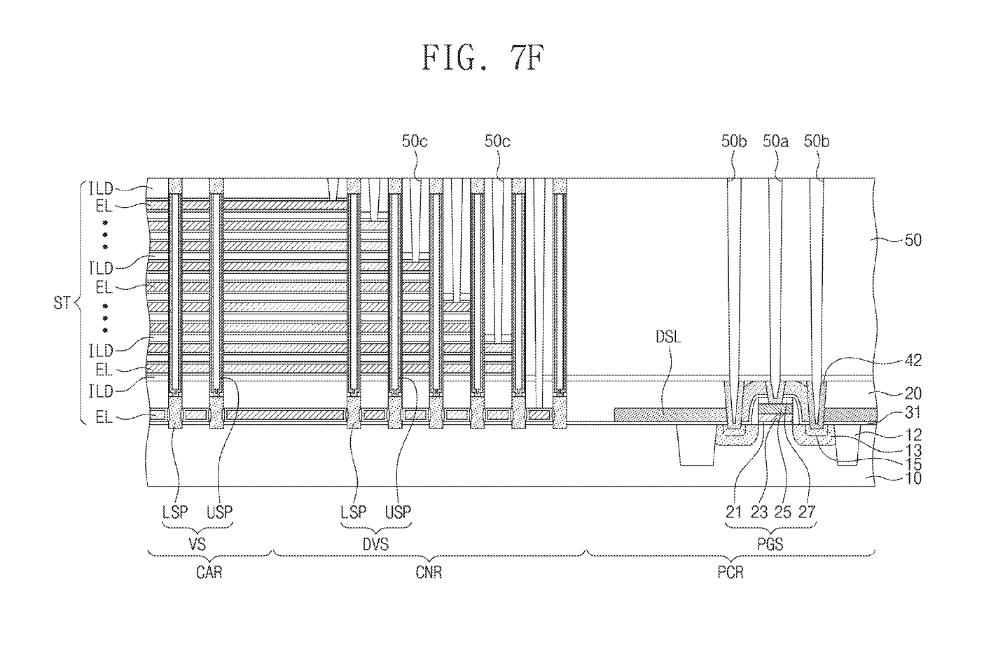

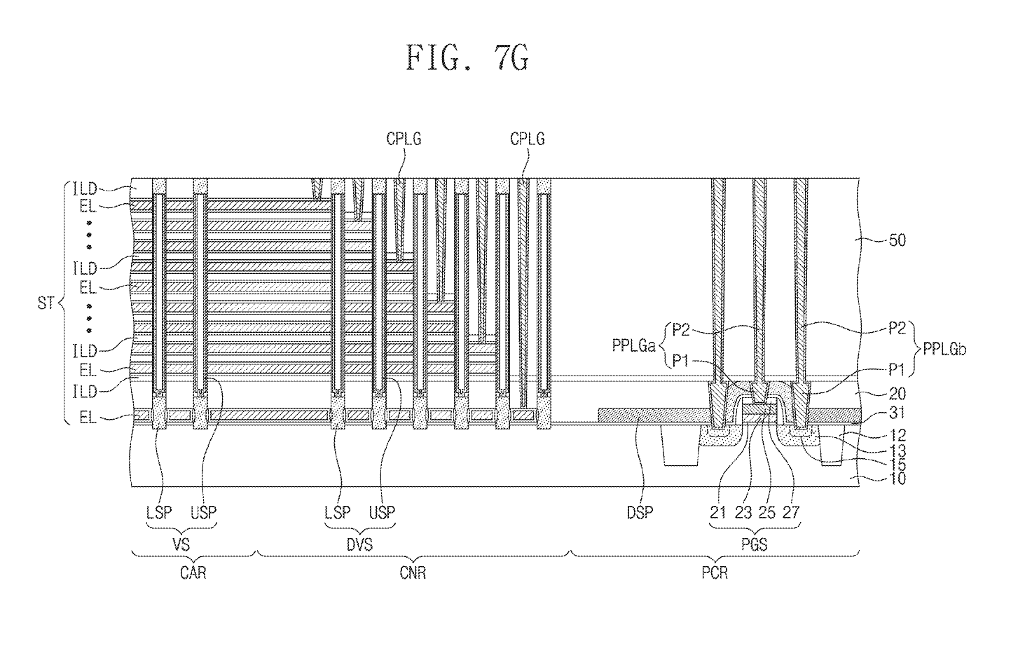

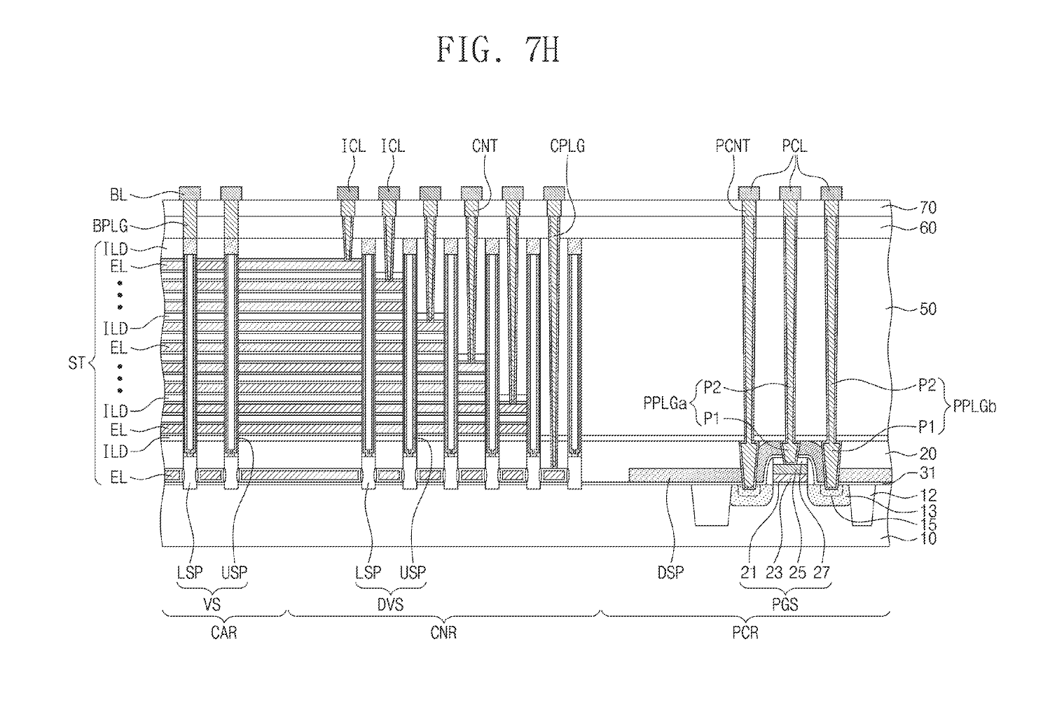

FIGS. 7A to 7H are sectional views illustrating a method of fabricating a three-dimensional semiconductor memory device according to various embodiments of inventive concepts.

For concise description, an element or step previously described with reference to FIGS. 2A to 2J may be identified by a similar or identical reference number without repeating an overlapping description thereof.

Referring to FIG. 7A, a buffer insulating layer 11 and a lower sacrificial layer may be formed, e.g. sequentially formed, covering the substrate 10, on which the peripheral gate stack PGS and the source/drain impurity regions 13 are formed.

The lower sacrificial layer may be formed conformally covering the top surface of the substrate 10 and the peripheral gate stack PGS. The lower sacrificial layer may be formed of a material having an etch selectivity with respect to the buffer insulating layer 11. The buffer insulating layer 11 may be extended from a region between the lower sacrificial layer and the substrate 10 and may be between the lower sacrificial layer and the peripheral gate stack PGS. The buffer insulating layer 11 may be or may include a silicon oxide layer and may be formed by using a thermal oxidation process or a deposition process.

In some embodiments, the lower sacrificial layer may be partially etched between the peripheral circuit region PCR and the connection region CNR. Accordingly, a lower sacrificial pattern LSL may be formed on the cell array region CAR and the connection region CNR, and a dummy sacrificial pattern DSL may be formed on the peripheral circuit region PCR.

Next, a lower planarized insulating layer 20 may be formed on the substrate 10. The lower planarized insulating layer 20 may be deposited to have a uniform thickness on the lower sacrificial pattern LSL and the dummy sacrificial pattern DSL. The lower planarized insulating layer 20 may have a top surface that is planarized by a planarization process, and may be substantially coplanar with the highest top surface of the dummy sacrificial pattern DSL.

Referring to FIG. 7B, the lower contact holes 33a and 33b may be formed, penetrating the lower planarized insulating layer 20 and the dummy sacrificial pattern DSL. The lower contact holes 33a and 33b may include the first lower contact holes 33a, which are formed exposing the peripheral gate stack PGS, and the second lower contact holes 33b, which are formed exposing the source/drain impurity regions 13, respectively.

After the formation of the lower contact holes 33a and 33b, dummy impurity regions 15 may be formed by doping the source/drain impurity regions 13 with second impurities (e.g., at least one of carbon (C), nitrogen (N), or fluorine (F)), as previously described with reference to FIG. 2B.

Referring to FIG. 7C, the sacrificial plug 42 and the sacrificial gapfill pattern 44 may be formed in each of the lower contact holes 33a and 33b.

In some embodiments, the top surfaces of the sacrificial plug 42 and the sacrificial gapfill pattern 44 may be substantially coplanar with the top surface of the lower planarized insulating layer 20. The sacrificial plug 42 may be formed of a material having an etch selectivity with respect to the lower planarized insulating layer 20 and the dummy sacrificial pattern DSL.

Referring to FIG. 7D, the mold structure 110, in which the sacrificial and insulating layers SL and ILD are alternatingly stacked, may be formed on the lower planarized insulating layer 20.

The mold structure 110 may have a staircase structure on the lower planarized insulating layer 20 on the connection region CNR. When the mold structure 110 is formed, the dummy sacrificial pattern DSL on the peripheral circuit region PCR may be exposed, or the top surface of the sacrificial plug 42 on the peripheral circuit region PCR may be exposed.

Referring to FIG. 7E, after the formation of the mold structure 110, the upper planarized insulating layer 50 may be formed on the substrate 10. The upper planarized insulating layer 50 may extend from the cell array region CAR to the peripheral circuit region PCR and may have a substantially flat top surface.

After the formation of the upper planarized insulating layer 50, the vertical structures VS and the dummy vertical structures DVS may be formed, as previously described with reference to FIG. 2F. In such embodiments, the vertical structures VS and the dummy vertical structures DVS may be formed penetrating the mold structure 110, the lower planarized insulating layer 20, the lower sacrificial pattern LSL, and the buffer insulating layer 11 and may be connected to the substrate 10.

Referring to FIG. 7F, the electrode structure ST may be formed by replacing the lower sacrificial pattern LSL and the sacrificial layers SL with the electrodes EL. As previously described with reference to FIG. 2G, the replacing of the lower sacrificial pattern LSL and the sacrificial layers SL with the electrodes EL may include forming trenches, removing the lower sacrificial pattern LSL and the sacrificial layers SL exposed by the trenches, to form gate regions, and forming the electrodes EL in the gate regions, respectively.

After the formation of the electrode structure ST, the first interlayered insulating layer 60 and the upper planarized insulating layer 50 may be patterned to form the cell contact holes 50c on the connection region CNR and the upper contact holes 50a and 50b on the peripheral circuit region PCR.

When the upper contact holes 50a and 50b are formed in the upper planarized insulating layer 50, the sacrificial gapfill pattern 44 may be removed exposing the sacrificial plugs 42. The cell contact holes 50c may be formed exposing end portions of the electrodes EL on the connection region CNR, and the cell contact hole exposing the lowermost one of the electrodes EL may be formed penetrating the first interlayered insulating layer 60, the upper planarized insulating layer 50, and the lower planarized insulating layer 20.

Next, the sacrificial plugs 42 exposed by the upper contact holes 50a and 50b may be removed to form the lower contact holes 33a and 33b exposing the dummy impurity regions 15. Here, the sacrificial plugs 42 may be removed using an etch recipe, which is selected to have an etch selectivity with respect to the lower planarized insulating layer 20 and the dummy sacrificial pattern DSL. As a result of the removal of the sacrificial plugs 42, the substrate 10 may be exposed by the lower contact holes 33a and 33b, and the dummy impurity region 15 may prevent, or reduce the likelihood of, the substrate 10, which is exposed by the lower contact holes 33a and 33b, from being etched or damaged during the etching process of removing the sacrificial plugs 42.

Referring to FIG. 7G, the cell contact plugs CPLG may be formed in the cell contact holes 50c and on the connection region CNR, and the first and second peripheral contact plugs PPLGa and PPLGb may be formed in the lower and upper contact holes 33a, 33b, 50a, and 50b and on the peripheral circuit region PCR.

As described with reference to FIG. 2I, each of the first and second peripheral contact plugs PPLGa and PPLGb may include the lower portion P1, which is formed penetrating the lower planarized insulating layer 20, and the upper portion P2, which is continuously extended from the lower portion P1 and is formed penetrating the upper planarized insulating layer 50 and the first interlayered insulating layer 60.

In some embodiments, the lower portion P1 of each of the first and second peripheral contact plugs PPLGa and PPLGb may have a top surface that is located between the lowermost one and the second lowermost one of the electrodes EL. Top surfaces of the first and second peripheral contact plugs PPLGa and PPLGb may be located at a level higher than that of the lower semiconductor pattern LSP.

Referring to FIG. 7H, the second interlayered insulating layer 70 may be formed on the first interlayered insulating layer 60 covering top surfaces of the cell contact plugs CPLG and the first and second peripheral contact plugs PPLGa and PPLGb.

As described above, the bit line contact plugs BPLG, the connection contact plugs CNT, and the peripheral connection contact plugs PCNT may be formed in the second interlayered insulating layer 70. In addition, the bit lines BL, the interconnection lines ICL, and the peripheral connection lines PCL may be formed on the second interlayered insulating layer 70.

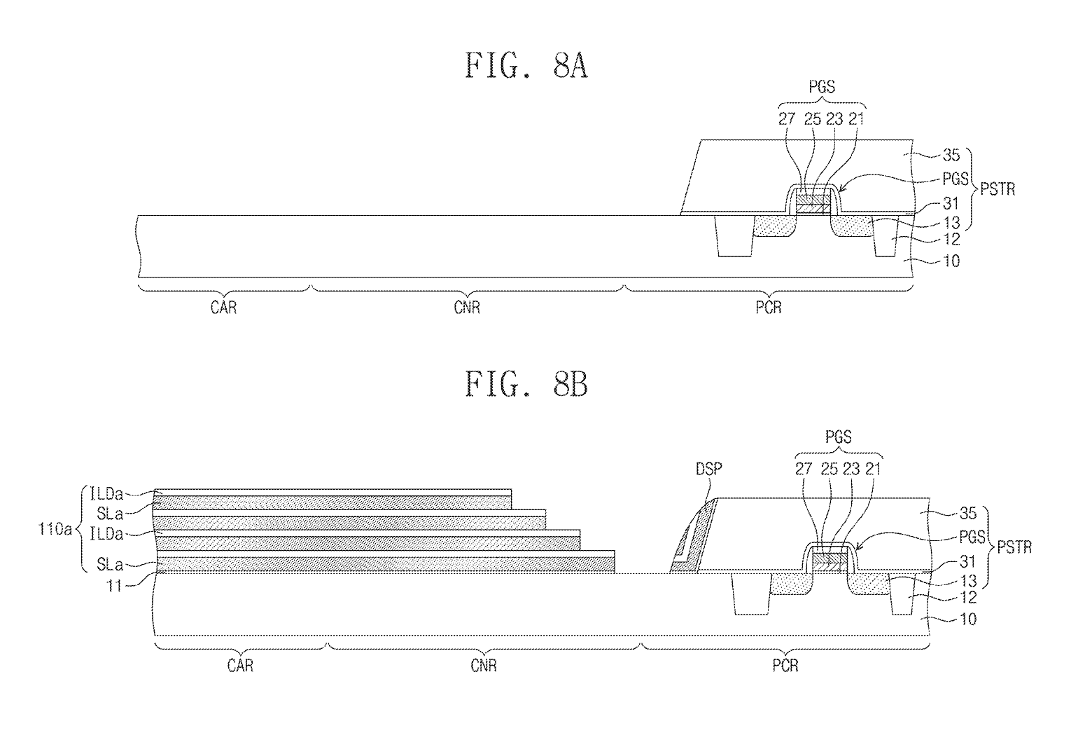

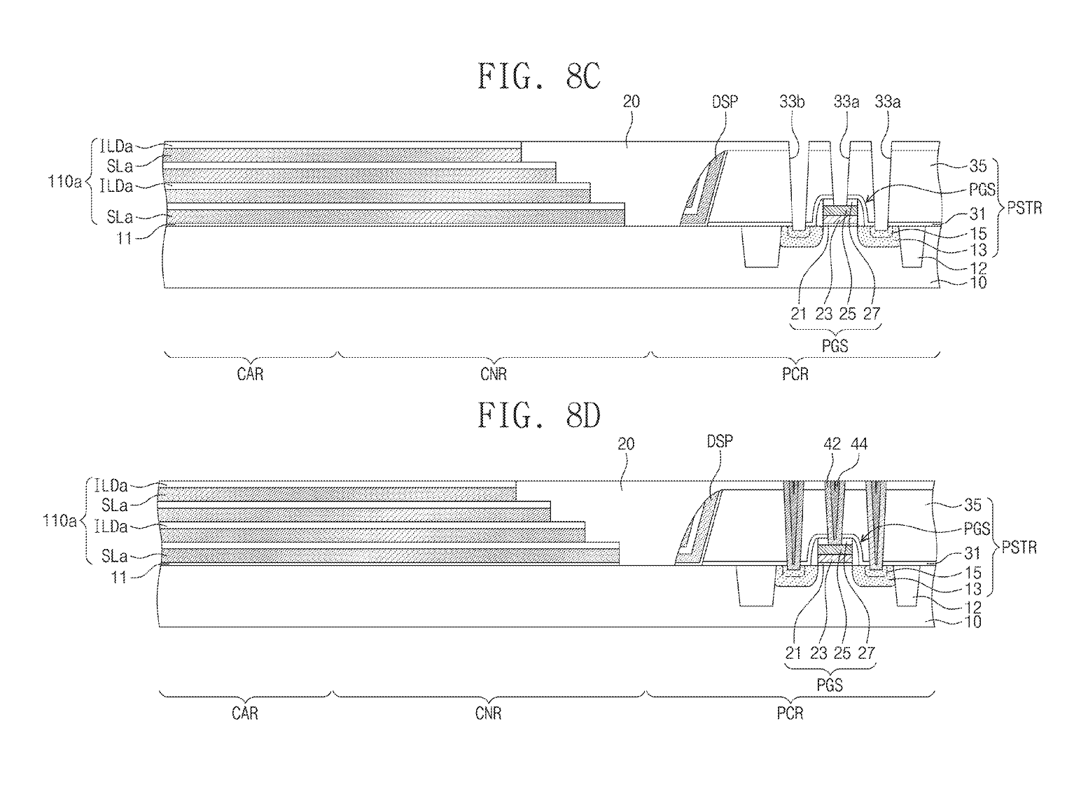

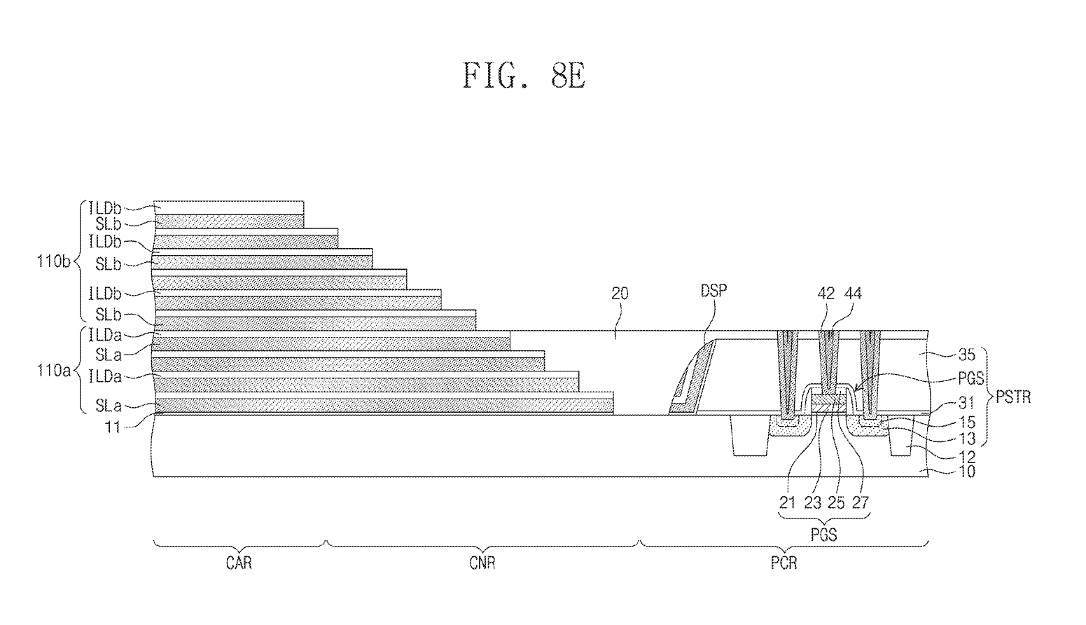

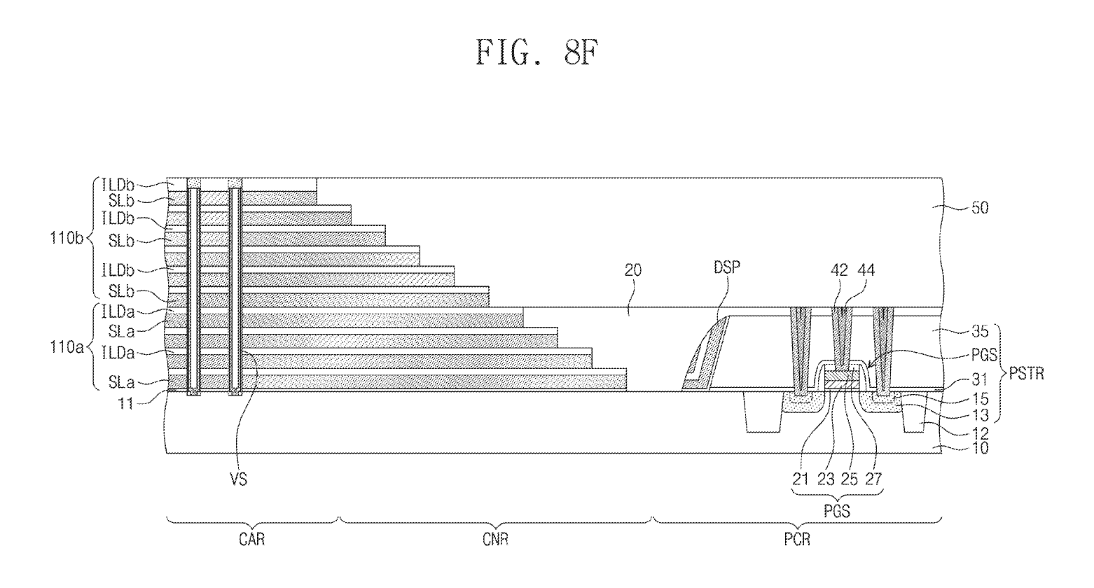

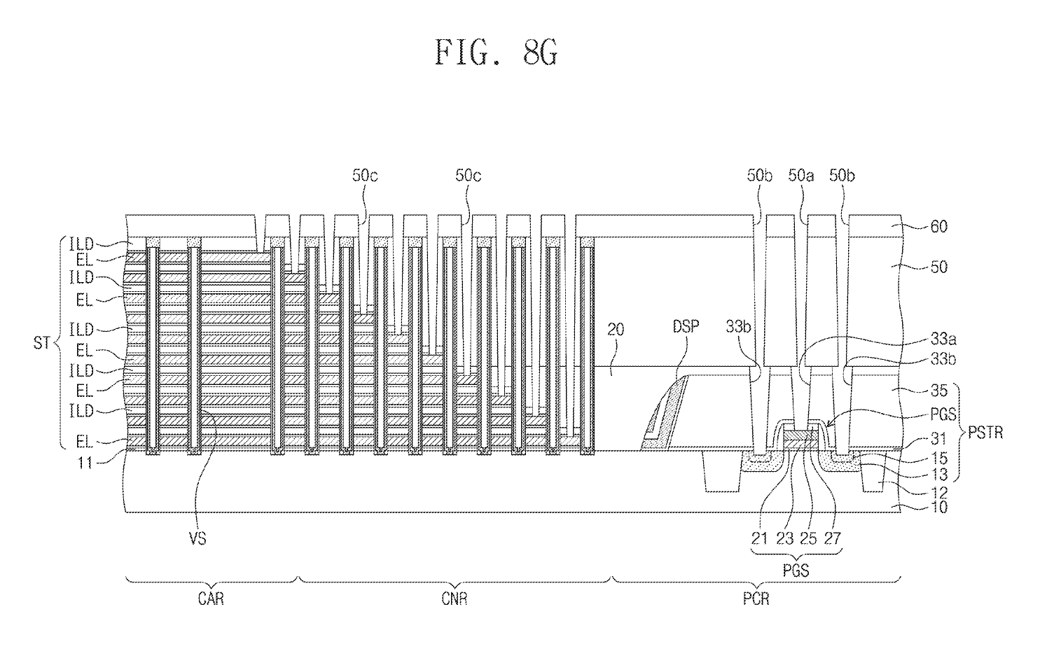

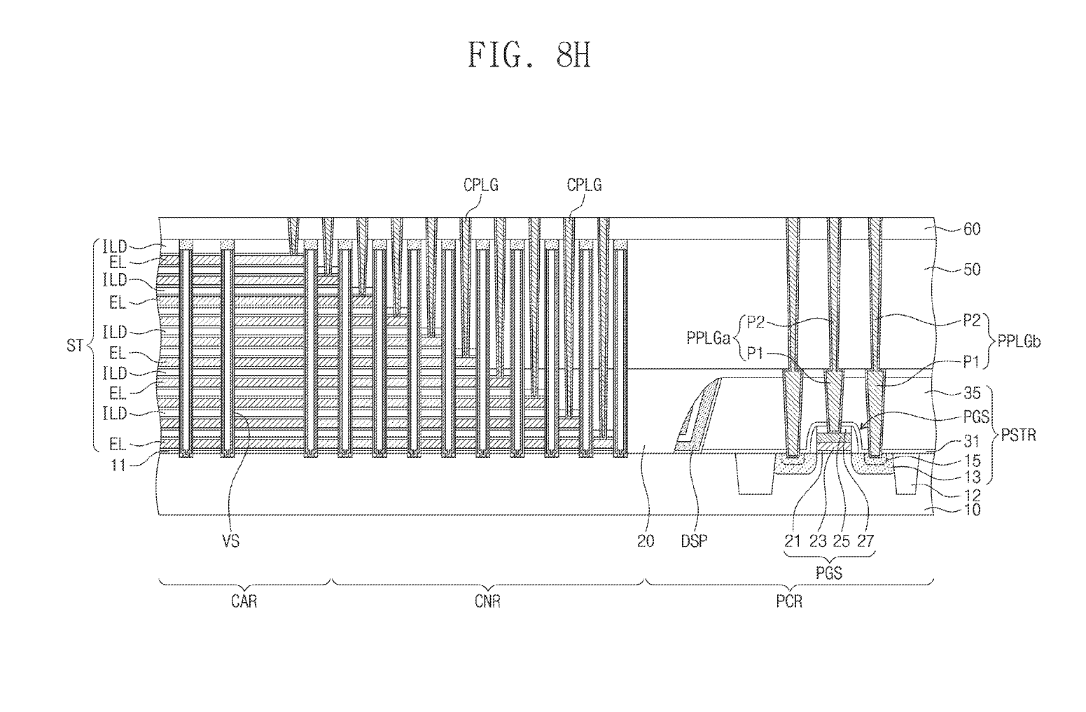

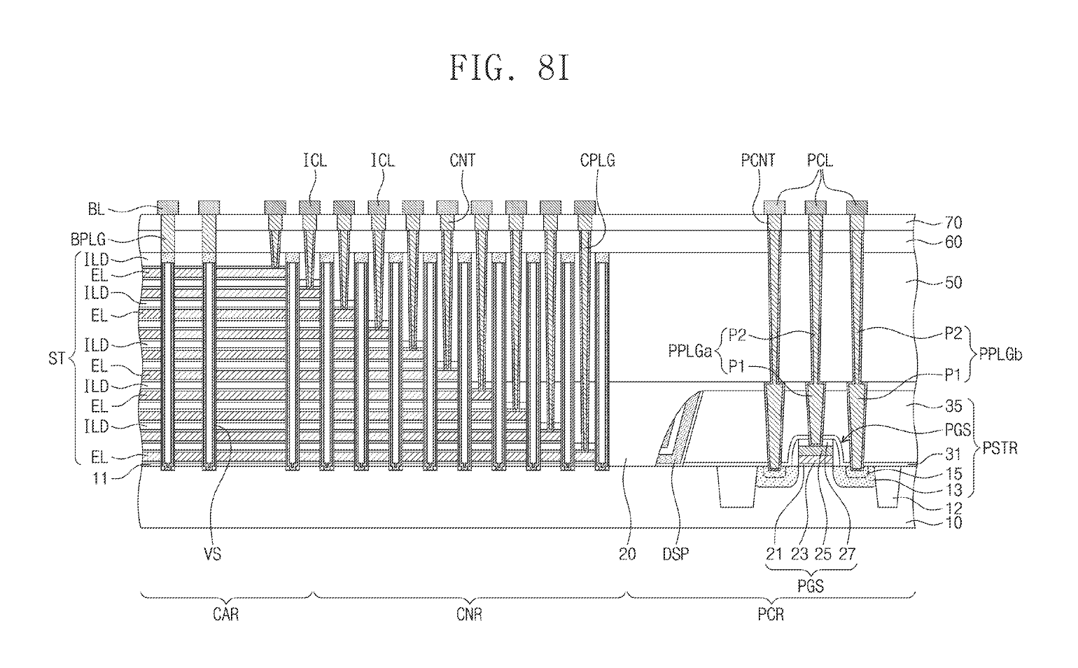

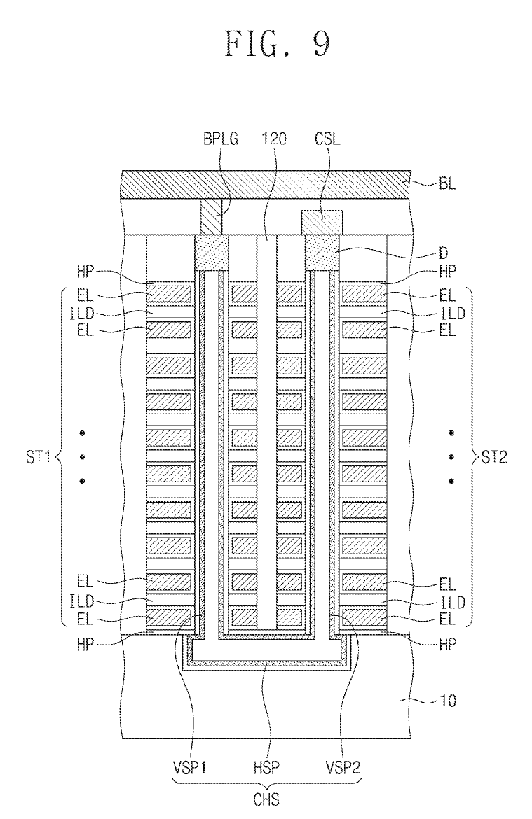

FIGS. 8A to 8I are sectional views illustrating a method of fabricating a three-dimensional semiconductor memory device according to various embodiments of the inventive concept.

For concise description, an element or step previously described with reference to FIGS. 2A to 2J may be identified by a similar or identical reference number without repeating an overlapping description thereof.

In the embodiments of FIGS. 8A to 8H, the dummy impurity region 15 and the sacrificial plug 42 may be formed after the formation of a part (e.g., the lower mold structure 110a) of the mold structure 110.

Referring to FIG. 8A, the peripheral logic structure PSTR may be formed on the peripheral circuit region PCR of the substrate 10. Here, the peripheral logic structure PSTR may include the peripheral gate stack PGS, the source/drain impurity regions 13, and the peripheral insulating pattern 35. The peripheral insulating pattern 35 may be formed covering the peripheral gate stack PGS and the source/drain impurity regions 13 and exposing the cell array region CAR and the connection region CNR of the substrate 10.

Referring to FIG. 8B, a lower mold structure 110a may be formed on the cell array region CAR and the connection region CNR of the substrate 10.

The lower mold structure 110a may include lower sacrificial layers SLa and lower insulating layers, which are vertically and alternatingly stacked on the substrate 10. The formation of the lower mold structure 110a may include alternatingly stacking the lower sacrificial layers SLa and the lower insulating layers on the substrate 10 provided with the peripheral logic structure PSTR and then performing a trimming process on the lower sacrificial layers SLa and the lower insulating layers. Accordingly, the lower mold structure 110a may have a staircase structure on the connection region CNR.

Furthermore, during the formation of the lower mold structure 110a, the dummy spacer DSP may be formed on a side surface of the peripheral insulating pattern 35. The dummy spacer DSP may be or include remaining portions of the lower sacrificial layers SLa and the lower insulating layers, which are not etched by an anisotropic etching process.

Referring to FIG. 8C, the lower planarized insulating layer 20 may be formed on the substrate 10. The lower planarized insulating layer 20 may be formed filling a gap region between the lower mold structure 110a and the peripheral logic structure PSTR and having a substantially flat top surface.

The lower planarized insulating layer 20 may be formed by forming an insulating layer covering the substrate 10 and performing a planarization process on the insulating layer. The lower planarized insulating layer 20 may be formed covering the peripheral logic structure PSTR.

Next, the first and second lower contact holes 33a and 33b may be formed penetrating the lower planarized insulating layer 20 and the peripheral insulating pattern 35. After the formation of the first and second lower contact holes 33a and 33b, the dummy impurity regions 15 may be formed in the source/drain impurity regions 13, as described above.

Referring to FIG. 8D, the sacrificial plug 42 and the sacrificial gapfill pattern 44 may be formed in each of the first and second lower contact holes 33a and 33b, after the formation of the dummy impurity regions 15.

Referring to FIG. 8E, an upper mold structure 110b may be formed on the lower mold structure 110a.

The upper mold structure 110b may include upper sacrificial layers SLb and upper insulating layers ILDb, which are vertically and alternatingly stacked on the lower mold structure 110a. The upper mold structure 110b may be formed by alternatingly stacking the upper sacrificial layers SLb and the upper insulating layers ILDb on the substrate 10 and performing a trimming process on the upper sacrificial layers SLb and the upper insulating layers ILDb. The upper mold structure 110b may be formed having a stepwise structure on the connection region CNR.

When the upper mold structure 110b is formed, top surfaces of the sacrificial plugs 42 and the sacrificial gapfill patterns 44 on the peripheral circuit region PCR may be exposed.

Referring to FIG. 8F, the upper planarized insulating layer 50 may be formed on the peripheral logic structure PSTR and the lower planarized insulating layer 20 covering the upper mold structure 110b.

After the formation of the upper planarized insulating layer 50, the vertical structures VS may be formed penetrating the lower and upper mold structures 110a and 110b. In some embodiments, the formation of the vertical structures VS may include forming vertical holes which penetrate the lower and upper mold structures 110a and 110b and expose the substrate 10, forming a vertical semiconductor pattern in each of the vertical holes which contact with the substrate 10, and then forming the vertical insulating pattern VP between the vertical semiconductor pattern and the lower and upper mold structures 110a and 110b.

During the formation of the vertical structures VS, the dummy vertical structures DVS may be formed on the connection region CNR penetrating the lower and upper mold structures 110a and 110b, as described above.

Referring to FIG. 8G, the first interlayered insulating layer 60 may be formed, after the formation of the vertical structures VS and the dummy vertical structures DVS. The first interlayered insulating layer 60 may be formed on the upper planarized insulating layer 50 covering top surfaces of the vertical structures VS and the dummy vertical structures DVS.

Next, the lower sacrificial layers SLa and the upper sacrificial layers SLb may be replaced with the electrodes EL. As a result, the electrode structure ST, in which the electrodes EL are vertically stacked on the substrate 10, may be formed.

After the formation of the electrode structure ST, the cell contact holes 50c and the upper contact holes 50a and 50b may be formed penetrating the first interlayered insulating layer 60 and the upper planarized insulating layer 50, as described above. The cell contact holes 50c may be formed exposing end portions of the electrodes EL, respectively, and the upper contact holes 50a and 50b may be formed exposing the sacrificial plugs 42, respectively.

Next, the sacrificial plugs 42 exposed by the upper contact holes 50a and 50b may be removed exposing inner surfaces of the lower contact holes 33a and 33b and the dummy impurity region 15.

Referring to FIG. 8H, the cell contact plugs CPLG may be formed in the cell contact holes 50c and on the connection region CNR, and the first and second peripheral contact plugs PPLGa and PPLGb may be formed in the lower and upper contact holes 33a, 33b, 50a, and 50b and on the peripheral circuit region PCR. Each of the first and second peripheral contact plugs PPLGa and PPLGb may include the lower portion P1 and the upper portion P2, as described above. In some embodiments, a vertical length of the lower portion P1 of each of the first and second peripheral contact plugs PPLGa and PPLGb may be changed depending on a thickness of the peripheral insulating pattern 35 and/or a thickness of the lower planarized insulating layer 20.

Referring to FIG. 8I, the second interlayered insulating layer 70 may be formed on the first interlayered insulating layer 60 covering top surfaces of the cell contact plugs CPLG and the first and second peripheral contact plugs PPLGa and PPLGb.

The bit line contact plugs BPLG, the connection contact plugs CNT, and the peripheral connection contact plugs PCNT may be formed in the second interlayered insulating layer 70, as described above. Also, the bit lines BL, the interconnection lines ICL, and the peripheral connection lines PCL may be formed on the second interlayered insulating layer 70.

FIG. 9 is a sectional view of a three-dimensional semiconductor memory device according to various embodiments of inventive concepts.

Referring to FIG. 9, first and second electrode structures ST1 and ST2 may be provided on the cell array region of the substrate 10 to be spaced apart from each other. Each of the first and second electrode structures ST1 and ST2 may include the electrodes EL and the insulating layers ILD, which are alternatingly stacked on the substrate 10. In some embodiments, the first and second electrode structures ST1 and ST2 may extend in a direction, and an insulating gapfill layer 120 may be provided between the first and second electrode structures ST1 and ST2.

A channel structure CHS may include first vertical semiconductor pillars VSP1 penetrating the first electrode structure ST1, and second vertical semiconductor pillars VSP2 penetrating the second electrode structure ST2, and a horizontal semiconductor pattern HSP connecting the first and second vertical semiconductor pillars VSP1 and VSP2 to each other.

The first and second vertical semiconductor pillars VSP1 and VSP2 may be provided in vertical holes that are formed penetrating the first and second electrode structures ST1 and ST2. Each of the first and second vertical semiconductor pillars VSP1 and VSP2 may include a conductive pad D provided at the highest level thereof. The first vertical semiconductor pillar VSP1 may be connected to the bit line BL, and the second vertical semiconductor pillar VSP2 may be connected to a common source line CSL.

The horizontal semiconductor pattern HSP may be provided in a horizontal recess region, which is formed in the substrate 10. The horizontal semiconductor pattern HSP may be horizontally extended from a region below the first electrode structure ST1 to another region below the second electrode structure ST2 and may connect the first and second vertical semiconductor pillars VSP1 and VSP2 to each other.

A peripheral contact plug may be connected to a MOS transistor through a contact hole. According to some embodiments of inventive concepts, upper and lower regions of the contact hole may be formed separately, and thus, when the number of electrodes stacked on a cell array region is increased, increasing a process margin in a process for forming the contact hole may be possible.

A sacrificial plug is used to form the peripheral contact plug, and this may make it possible filling the upper and lower regions of the contact hole with a conductive material at a time.

A dummy impurity region may be formed on a source/drain impurity region. Thus, preventing, or reducing the likelihood of, the source/drain impurity region from being damaged when the sacrificial plug is removed may be possible.

While example embodiments of inventive concepts have been particularly shown and described, it will be understood by one of ordinary skill in the art that variations in form and detail may be made therein without departing from the spirit and scope of the attached claims.

1. A three-dimensional semiconductor memory device, comprising:
a substrate including a peripheral circuit region and a cell array region;
an electrode structure including a plurality of electrodes vertically stacked on the cell array region of the substrate;
a peripheral logic circuit provided on the peripheral circuit region of the substrate, the peripheral logic circuit including a first impurity region doped with first impurities;
a peripheral contact plug connected to the first impurity region; and
a second impurity region between the first impurity region and the peripheral contact plug, the second impurity region being including second impurities different from the first impurities,
wherein the peripheral contact plug includes a lower portion contacting the second impurity region, and an upper portion continuously extending from the lower portion,
a lower width of each of the lower and upper portions is less than an upper width thereof, and
the upper width of the lower portion is greater than the lower width of the upper portion.

2. The device of claim 1, wherein the peripheral contact plug has a bottom surface spaced apart from the first impurity region.

3. The device of claim 1, wherein the peripheral contact plug has a bottom surface located below a top surface of the substrate.

4. The device of claim 1, wherein the second impurity region has a depth less than that of the first impurity region.

5. The device of claim 1, wherein a width of the second impurity region is less than a width of the first impurity region.

6. The device of claim 1, wherein the second impurity region contains at least one of carbon (C), nitrogen (N), or fluorine (F).

7. The device of claim 1, wherein a vertical length of the lower portion of the peripheral contact plug is less than a vertical length of the upper portion thereof.

8. The device of claim 1, wherein a top surface of the upper portion of the peripheral contact plug is above a top surface of an uppermost one of the electrodes.

9. The device of claim 1, further comprising:
a lower insulating layer covering the peripheral logic circuit; and
an upper insulating layer covering the electrode structure and the lower insulating layer,
wherein a bottom surface of the upper insulating layer partially covers a top surface of the lower portion of the peripheral contact plug.

10. The device of claim 9, further comprising:
cell contact plugs penetrating the upper insulating layer and are respectively connected to end portions of the electrodes of the electrode structure,
wherein the peripheral contact plug has a top surface that is coplanar with top surfaces of the cell contact plugs.

11. The device of claim 1, further comprising:
a plurality of vertical structures penetrating the electrode structure and connected to the substrate,
wherein each of the vertical structures includes a lower semiconductor pattern penetrating a lower portion of the electrode structure and connected to the substrate, and an upper semiconductor pattern, penetrating an upper portion of the electrode structure and connected to the lower semiconductor pattern, and
a top surface of the lower semiconductor pattern being located below a top surface of the lower portion of the peripheral contact plug.

12. A three-dimensional semiconductor memory device, comprising:
a substrate including a peripheral circuit region and a cell array region;
an electrode structure including a plurality of electrodes vertically stacked on the cell array region of the substrate;
a peripheral logic circuit provided on the peripheral circuit region of the substrate, the peripheral logic circuit comprising a peripheral gate stack and source/drain impurity regions, the peripheral gate stack including a first side and a second side, the source/drain regions being at both sides of the peripheral gate stack; and
peripheral contact plugs connected to the source/drain impurity regions, respectively,
wherein each of the source/drain impurity regions includes,
a first impurity region doped with first impurities, and
a second impurity region including second impurities different from the first impurities,
wherein the peripheral contact plugs are in contact with the second impurity regions of the source/drain impurity regions.

13. The device of claim 12, wherein each of the peripheral contact plugs comprises:
a lower portion in contact with the second impurity region; and
an upper portion continuously extending from the lower portion,
wherein each of the lower and upper portions has a lower width less than an upper width, and
the upper width of the lower portion is greater than the lower width of the upper portion.

14. The device of claim 12, wherein the lower and upper portions of the peripheral contact plug are continuously extended and do not have an interface therebetween.

15. The device of claim 12, wherein the second impurity regions of the source/drain impurity regions are co-doped with the first impurities and the second impurities.

16. The device of claim 12, wherein the second impurity region has a depth less than that of the first impurity region.

17. The device of claim 12, wherein a width of the second impurity region is less than a width of the first impurity region.

18. The device of claim 12, further comprising:
a plurality of vertical structures penetrating the electrode structure and connected to the substrate,
wherein each of the vertical structures includes a lower semiconductor pattern penetrating a lower portion of the electrode structure and is connected to the substrate, and an upper semiconductor pattern penetrating an upper portion of the electrode structure and connected to the lower semiconductor pattern, and
a top surface of the lower semiconductor pattern is located below a top surface of the lower portion of the peripheral contact plug.

19.-25. (canceled)
